(19) United States
(12) Patent Application Publication
(10) Pub. No.: US 2024/0365605 A1
(43) Pub. Date: Oct. 31, 2024

(54) DISPLAY PANEL AND METHOD FOR MANUFACTURING THE SAME

(71) Applicant: Samsung Display Co., LTD., Yongin-si (KR)

(72) Inventors: JINHO JU, Yongin-si (KR); KIJUNE LEE, Yongin-si (KR)

(21) Appl. No.: 18/426,779

(22) Filed: Jan. 30, 2024

(30) Foreign Application Priority Data
Apr. 27, 2023 (KR) 10-2023-0055326

(51) Int. Cl. H10K 59/124; H10K 59/12

(52) U.S. Cl. CPC H10K 59/124; H10K 59/1201

(57) ABSTRACT

A display panel includes a base layer including a boundary region and a pixel region, a pixel circuit including a first transistor including a first semiconductor pattern and a first gate and overlapped with the pixel region, and a plurality of insulating layers where an opening defined in the plurality of insulating layers corresponds to the boundary region. A first insulating layer of the plurality of insulating layers covers the first gate, and a groove defined in the first insulating layer is spaced apart from the opening. The groove is formed through a portion of the first insulating layer.

### CROSS-REFERENCE TO RELATED APPLICATIONS

This application claims priority to Korean Patent Application No. 10-2023-0055326, filed on Apr. 27, 2023, and all the benefits accruing therefrom under 35 U.S.C. § 119, the content of which in its entirety is herein incorporated by reference.

### BACKGROUND

Embodiments of the present disclosure described herein relate to a display panel including a boundary region and a method for manufacturing the same.

A display device may include a display panel, and the display panel may include a light emitting element and transistors to control an electrical signal applied to the light emitting element. Recently, with the development of some technologies, a flexible display device including a flexible display panel has been developed. For example, various flexible display devices, which may be changed in shape to a curved shape, or bent, or rolled, have been developed. A flexible display device capable of various changes in shape may provide improved portability and improve user convenience. However, some flexible display panels may be weak or easily damaged due to an external impact. Accordingly, techniques for protecting transistors from external impact are desired.

### SUMMARY

Embodiments of the present disclosure provide a display panel robust to external impact and having increased reliability, and a method for manufacturing the same.

According to an embodiment, a display panel includes a base layer including a boundary region and a pixel region, a pixel circuit overlapped with the pixel region and including a first transistor including a first semiconductor pattern and a first gate, and a plurality of insulating layers, where an opening defined in the plurality of insulating layers corresponds to the boundary region. A first insulating layer of the plurality of insulating layers covers the first gate, and a groove defined in the first insulating layer is spaced apart from the opening. The groove is formed through a portion of the first insulating layer.

The groove by the first semiconductor pattern.

The opening may be formed through the plurality of insulating layers.

A depth of the opening may be greater than a depth of the groove, in a thickness direction.

The display panel further includes further includes a metal layer disposed at a layer the same as a layer at which the first gate is disposed.

A surface of the metal layer may be exposed by the groove.

The metal layer may include at least one of aluminum (Al), molybdenum (Mo), titanium (Ti), and indium gallium zinc oxide (IGZO).

The pixel circuit may further include a second transistor including a second semiconductor pattern and a second gate. The second transistor may be disposed at a layer different from a layer at which the first transistor is disposed.

The first semiconductor pattern may include an oxide semiconductor, and the second semiconductor pattern may include a silicon semiconductor.

According to an embodiment, a display panel includes a base layer including a boundary region and a pixel region, a pixel circuit overlapped with the pixel region and including a first transistor including a first semiconductor pattern and a first gate, and a plurality of insulating layers, where an opening defined in the plurality of insulating layers corresponds to the boundary region. A distance between the first semiconductor pattern and the opening is 5 μm or more and 70 μm or less in a direction perpendicular to a thickness direction.

The opening may be formed through the plurality of insulating layers.

The first semiconductor pattern may include an oxide semiconductor.

The display panel may further include a barrier layer disposed on the base layer, and the barrier layer may be exposed by the opening.

The pixel circuit may include a second transistor including a second semiconductor pattern and a second gate. The second transistor may be disposed at a layer different from a layer at which the first transistor is disposed, and the second semiconductor pattern may include a silicon semiconductor.

According to an embodiment, a method for manufacturing a display panel includes preparing a base layer including a boundary region and a pixel region, forming a transistor overlapped with the pixel region and including a semiconductor pattern and a gate, and forming an insulating layer covering the gate. An opening corresponding to the boundary region and a groove spaced apart from the opening are formed in the forming of the insulating layer, and the groove is formed through a portion of the insulating layer.

The method for manufacturing the display panel may further include forming a metal layer overlapped with the semiconductor pattern, after forming the transistor and before forming the first insulating layer.

The metal layer may include at least one of aluminum (Al), molybdenum (Mo), titanium (Ti), and indium gallium zinc oxide (IGZO).

The method for manufacturing the display panel may further include etching the insulating layer. A first etching depth associated with forming the groove may be less than a second etching depth associated with forming the opening.

Forming of the groove and the opening may be based on a half tone mask.

The semiconductor pattern may include an oxide semiconductor.

### BRIEF DESCRIPTION OF THE FIGURES

The above and other objects and features of the present disclosure will become apparent by describing in detail embodiments thereof with reference to the accompanying drawings.

FIG. 1A is a perspective view illustrating an embodiment of a display device according to aspects of the present disclosure.

FIG. 1B is a perspective view illustrating an embodiment of a display device according to aspects of the present disclosure.

FIG. 1C is a perspective view illustrating an embodiment of a display device according to aspects of the present disclosure.

FIG. 2 is an exploded perspective view illustrating an embodiment of a display device according to aspects of the present disclosure.

FIG. 3 is a cross-sectional view illustrating a portion taken along line I-I′ of FIG. 2.

FIG. 4 is a block diagram of an embodiment of a display device according to aspects of the present disclosure.

FIG. 5 is an equivalent circuit diagram of an embodiment of a pixel according to aspects of the present disclosure.

FIG. 6 is a waveform diagram of an embodiment of a driving signal for driving a pixel according to aspects of the present disclosure.

FIG. 7A is an enlarged plan view of an embodiment of a display panel, according to aspects of the present disclosure.

FIG. 7B is an enlarged plan view of an embodiment of a display panel, according to aspects of the present disclosure.

FIG. 7C is an enlarged plan view of an embodiment of a display panel, according to aspects of the present disclosure.

FIG. 8A is a cross-sectional view of an embodiment of a display panel, according to aspects of the present disclosure.

FIG. 8B is a cross-sectional view of an embodiment of a display panel, according to aspects of the present disclosure.

FIG. 8C is a cross-sectional view of an embodiment of a display panel, according to aspects of the present disclosure.

FIG. 8D is a cross-sectional view of an embodiment of a display panel, according to aspects of the present disclosure.

FIG. 9A is a plan view of an embodiment of a pixel region according to aspects of the present disclosure.

FIG. 9B is a cross-sectional view of an embodiment of a display panel, according to aspects of the present disclosure.

FIG. 9C is a cross-sectional view of an embodiment of a display panel according to aspects of the present disclosure.

FIG. 10 is a flowchart illustrating an embodiment of a method for manufacturing a display panel according to aspects of the present disclosure.

FIGS. 11A to 11C are views schematically illustrating steps of an embodiment of manufacturing a display panel according to aspects of the present disclosure.

FIGS. 12A to 12C are views schematically illustrating steps of an embodiment of manufacturing a display panel according to aspects of the present disclosure.

### DETAILED DESCRIPTION

While the present disclosure is susceptible to various modifications and alternative forms, specific embodiments thereof are shown by way of examples in the drawings and will herein be described in detail. It should be understood, however, that there is no intent to limit the present disclosure to the particular forms disclosed, but on the contrary, the present disclosure is to cover all modifications, equivalents, and alternatives falling within the spirit and scope of the aspects of the present disclosure.

In the specification, the expression that a first component (or region, layer, part, portion, etc.) is “on”, “connected to”, or “coupled to” a second component means that the first component is directly on, connected to, or coupled to the second component or means that a third component is interposed therebetween.

The same reference numerals refer to the same components. In addition, in drawings, thicknesses, proportions, and dimensions of components may be exaggerated to describe the technical features effectively. The expression “and/or” includes one or more combinations which associated components are capable of defining.

Although the terms “first”, “second”, etc. may be used to describe various components, the components should not be construed as being limited by the terms. The terms are used to distinguish one component from another component. For example, without departing from the scope and spirit of the present disclosure, a first component may be referred to as a second component, and similarly, the second component may be referred to as the first component. The singular forms are intended to include the plural forms unless the context clearly indicates otherwise.

Also, the terms “under”, “below”, “on”, “above”, etc. are used to describe the correlation of components illustrated in drawings. The terms that are relative in concept are described based on a direction shown in drawings.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

Unless otherwise defined, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

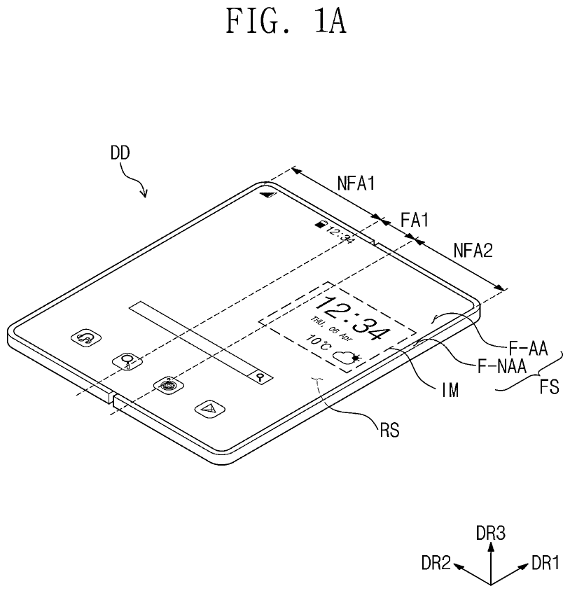

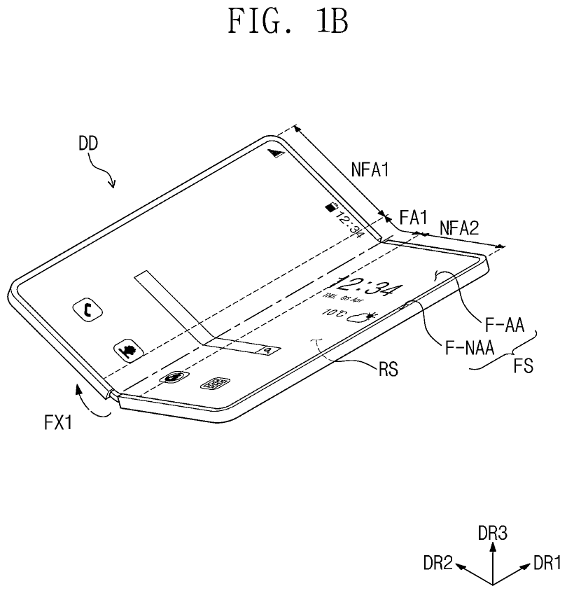

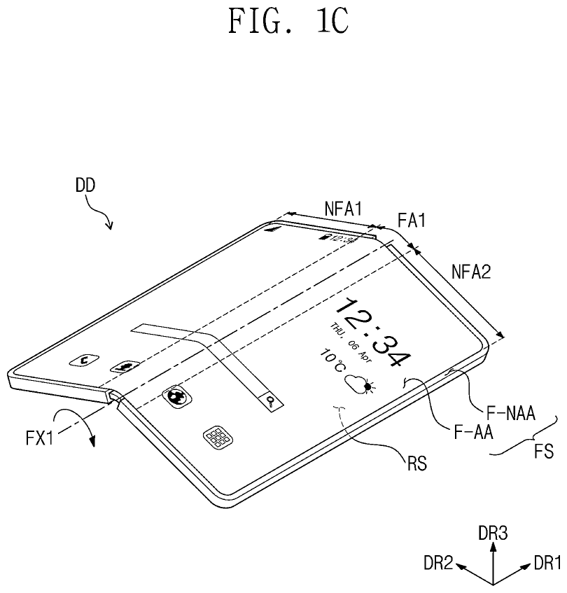

Below, embodiments of the present disclosure will be described with reference to accompanying drawings. FIG. 1A is a perspective view illustrating an embodiment of a display device according to aspects of the present disclosure. FIG. 1B is a perspective view illustrating an inner-folding process of a display device illustrated in FIG. 1A. FIG. 1C is a perspective view illustrating an outer-folding process of a display device illustrated in FIG. 1A.

According to an embodiment, a display device DD may be a device activated in response to an electrical signal. The display device DD may be a flexible display device. For example, the display device DD may be a cellular phone, a tablet PC, a car navigation system, a game console, a personal computer, a laptop computer, or a wearable device, but is not limited thereto. FIG. 1A illustrates that the display device DD is a cellular phone by way of example.

The display device DD may display an image IM through a display surface FS. The display surface FS may include an active region F-AA and a peripheral region F-NAA (also referred to herein as a non-active region F-NAA). The active region F-AA may be activated in response to an electrical signal. The display device DD may display the image IM through the active region F-AA. In some aspects, various types of external inputs may be sensed in the active region F-AA. The peripheral region F-NAA may be adjacent to the active region F-AA. The peripheral region F-NAA may surround the active region F-AA. Accordingly, the shape of the active region F-AA may be substantially defined by the peripheral region F-NAA. However, the shape is provided for illustrative purposes, and the peripheral region F-NAA may be disposed to be adjacent to a single side of the active region F-AA or may be omitted. The display surface FS may include a flat surface defined by a first directional axis DR1 and a second directional axis DR2.

A rear surface RS of the display device DD may be a surface facing the display surface FS. For example, the rear surface RS may function as a second display surface on which a video or an image is displayed. Alternatively, the video or the image may not be displayed on the rear surface RS serving as an outer surface of the display device DD.

The display device DD may sense an external input applied from the outside. The external input may include various types of inputs that provided from the outside of the display device DD. For example, as well as a contact by a part, such as, for example, a user hand, of a body, the external input may include an external input (for example, a hovering) which is applied in a state where the user hand approaches the display device DD or is adjacent to the display device DD within a given distance. In some aspects, the external input may be provided in various types such as, for example, force, pressure, temperature, or light.

In the examples described herein, the first directional axis DR1 and the second directional axis DR2 may be perpendicular to each other. A third directional axis DR3 may be a direction normal to the plane defined by the first directional axis DR1 and the second directional axis DR2. The thickness direction of the display device DD may be parallel to the third directional axis DR3. A top surface (or an upper side, an upper portion, or upper surface) and a bottom surface (or a lower side, a lower portion, or lower surface) may be defined based on the third directional axis DR3. The top surface (or the upper side, the upper portion, or upper surface) refers to a surface (or a direction or a part) adjacent to the display surface FS, and the bottom surface (or the lower side, the lower portion, or lower surface) refers to a surface (or the direction, or portion) adjacent to the rear surface RS. The cross-section refers to a surface parallel to the thickness direction DR3, and the plane may refer to a surface normal to the thickness direction DR3. The plane refers to a plane defined by the first directional axis DR1 and the second directional axis DR2.

The directions indicated by the first to third directional axes DR1, DR2, and DR3, which will be described in the specification, are relative and may be changed to other directions. In some aspects, the directions indicated by the first to third directional axes DR1, DR2, and DR3 will be referred to as the first to third directions and will be assigned with the same reference numerals.

The display device DD may include a folding region FA1 and non-folding regions NFA1 and NFA2. The display device DD may include a plurality of non-folding regions NFA1 and NFA2. The display device DD may include the first non-folding region NFA1 and the second non-folding region NFA2 which are disposed to be spaced apart from each other while interposing the folding region FA1 between the first non-folding region NFA1 and the second non-folding region NFA2.

Although FIGS. 1A to 1C illustrate the display device DD including one folding region FA1, which is provided for illustrative purposes, the display device DD may have a plurality of folding regions defined therein. In some aspects, the display device DD may be folded about a plurality of folding axes, such that portions of the display surface FS face each other. The number of the folding axes and the number of the non-folding regions depending on the number of the folding axes is not limited to any one embodiment.

Referring to FIGS. 1B and 1C, the display device DD may be folded about the first folding axis FX1. The first folding axis FX1 illustrated in FIGS. 1B and 1C is a virtual axis extending in the first direction DR1, and the first folding axis FX1 may be parallel to the direction of a longer side of the display device DD. However, the configuration is provided for illustrative purposes, and the embodiment is not limited thereto. Although not illustrated, the first folding axis FX1 may be parallel to a direction of a shorter side of the display device DD.

The first folding axis FX1 may extend in the first directional axis DR1 on the display surface FS, and may extend in the first directional axis DR1 under the rear surface RS. Referring to FIG. 1B, the first non-folding region NFA1 and the second non-folding region NFA2 face each other, and the display device DD may be inwardly folded such that the display surface S is not exposed to the outside. Referring to FIG. 1C, the display device DD may be folded about the first folding axis FX1 and may be changed to be in an outer-folded state in which one region, which is overlapped with the first non-folding region NFA1, of the rear surface RS faces another region, which is overlapped with the second non-folding region NFA2, of the rear surface RS.

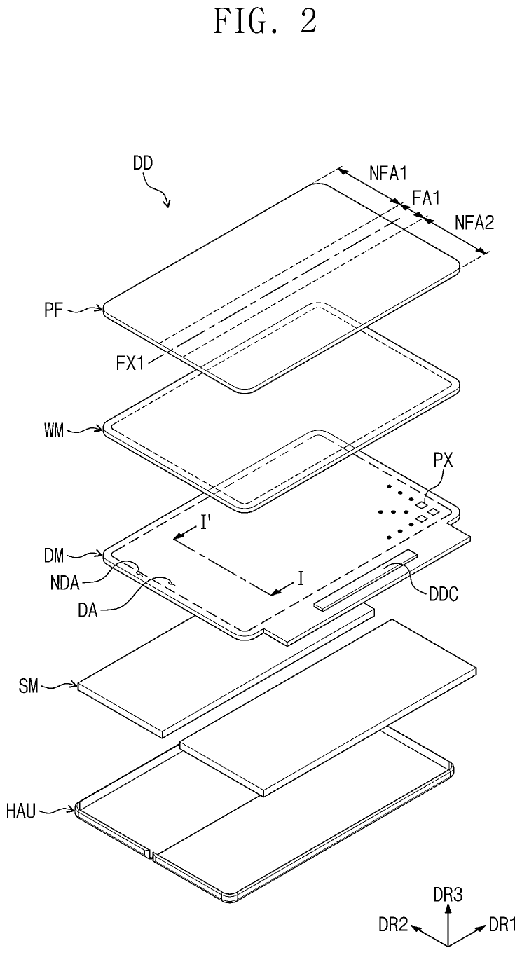

FIG. 2 is an exploded perspective view illustrating an embodiment of the display device DD according to aspects of the present disclosure. As illustrated in FIG. 2, the display device DD may include a display module DM and a window WM disposed on the display module DM. In some aspects, the display device DD may include a support member SM disposed under the display module DM, a protective layer PF disposed on the window WM, and a housing HAU to receive the display module DM.

The protective layer PF may be a functional layer to protect one surface of the window WM. The protective layer PF may include an anti-fingerprint coating agent, a hard coating agent, or an antistatic agent. Although not illustrated, an adhesion layer may be interposed between the window WM and the protective layer PF. The adhesion layer may include a typical adhesive agent, but the present disclosure is not limited to thereto.

The window WM may include a glass substrate. The window WM is to protect the display module DM. The image IM (see FIG. 1A) generated on the display module DM may be transmitted through the window WM to be provided to a user. For example, the window WM may include an ultra-thin glass (UTG).

The support member SM may include a metal material or a polymer material. For example, the support member SM may be formed of stainless steel, aluminum, or an alloy thereof. Alternatively or additionally, the support member SM may be formed of Carbon Fiber Reinforced Plastic (CFRP). However, the embodiment is not limited thereto. The support member SM may include a non-metal material, plastic, fiber reinforced plastic, or glass.

The housing HAU may include a material having relatively high rigidity. For example, the housing HAU may include a plurality of frames and/or plates including glass, plastic, or metal. The housing HAU may provide a specific receiving space. The display module DM may be received in a receiving space to be protected from external impact.

The display module DM may display an image in response to an electrical signal, and the display module DM may transmit/receive information on an external input. The display module DM may include a display region DA and a non-display region NDA. The display region DA may be defined as a region through which an image provided from the display module DM is output. A pixel PX may be disposed in the display region DA and not disposed in the non-display region NDA. A data driving circuit DDC may be provided at one side of the non-display region NDA.

The non-display region NDA may be adjacent to the display region DA. For example, the non-display region NDA may surround the display region DA. However, this is illustrated by way of example. The non-display region NDA may be defined in various shapes, and not limited to any one embodiment. The display region DA of the display module DM may correspond to at least a portion of the active region F-AA (see FIG. 1A).

Although not illustrated, the display device DD may further include a cushion layer or a shielding layer disposed under the support member SM. The cushion layer may include sponge, a foam, or elastomer such as, for example, urethane resin. The shielding layer may be an electromagnetic wave shielding layer or a heat dissipation layer.

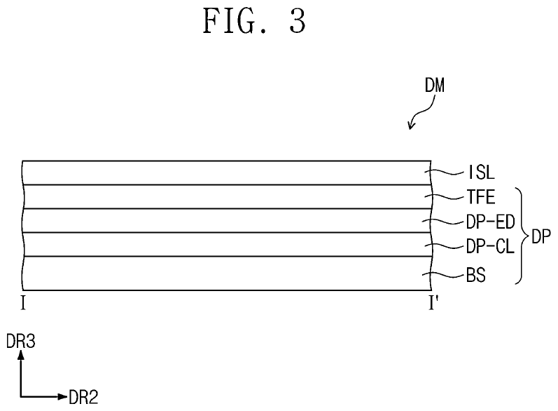

FIG. 3 is a cross-sectional view illustrating a portion taken along line I-I′ of FIG. 2. FIG. 3 is a cross-sectional view illustrating an embodiment of the display module DM according to aspects of the present disclosure. Referring to FIG. 3, the display module DM may include a display panel DP and an input sensing layer ISL directly disposed on the display panel DP. The display panel DP may be a component capable of generating the image.

The display panel DP may include a base layer BS, a circuit layer DP-CL, a display element layer DP-ED, and an encapsulation layer TFE sequentially stacked on each other. Although not illustrated, a functional layer may be further interposed between two layers adjacent to each other of the base layer BS, the circuit layer DP-CL, the display element layer DP-ED, and the encapsulation layer TFE.

The base layer BS may provide a base surface for disposing the circuit layer DP-CL. The base layer BS may be a flexible substrate allowing bending, folding, or rolling. The base layer BS may be a glass substrate, a metal substrate, or a polymer substrate. However, an embodiment is not limited thereto, and the base layer BS may be an inorganic layer, an organic layer, or a composite material layer.

The base layer BS may include a single layer or multiple-layers. For example, the base layer BS may include a first synthetic resin layer, a multi-layer or single-layer inorganic layer, and a second synthetic resin layer disposed on the multi-layer or single-layer inorganic layer. Each of the first synthetic resin layer and the second synthetic resin layer may include a polyimide-based resin. In some aspects, each of the first synthetic resin layer and the second synthetic resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In the present specification, the term “˜-based” resin means to include a functional group of “˜”.

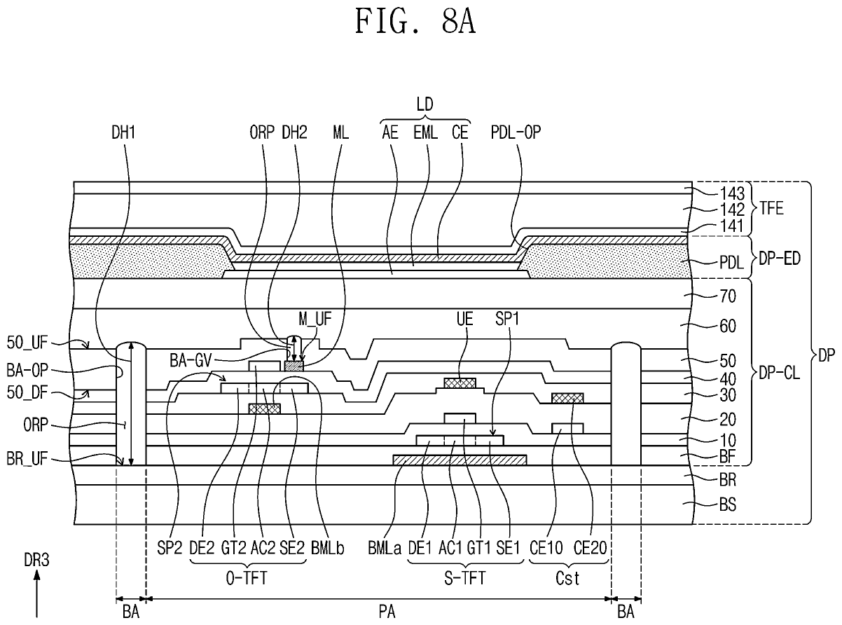

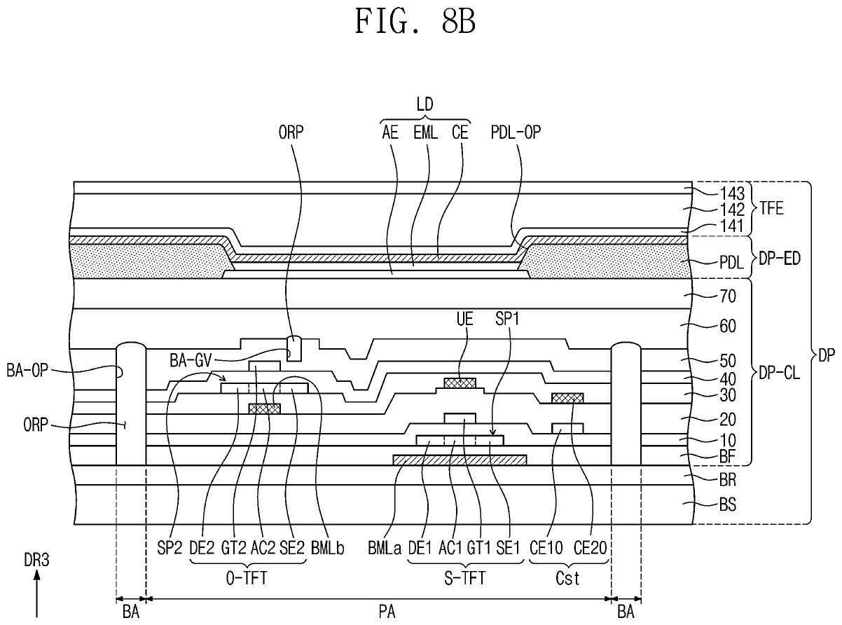

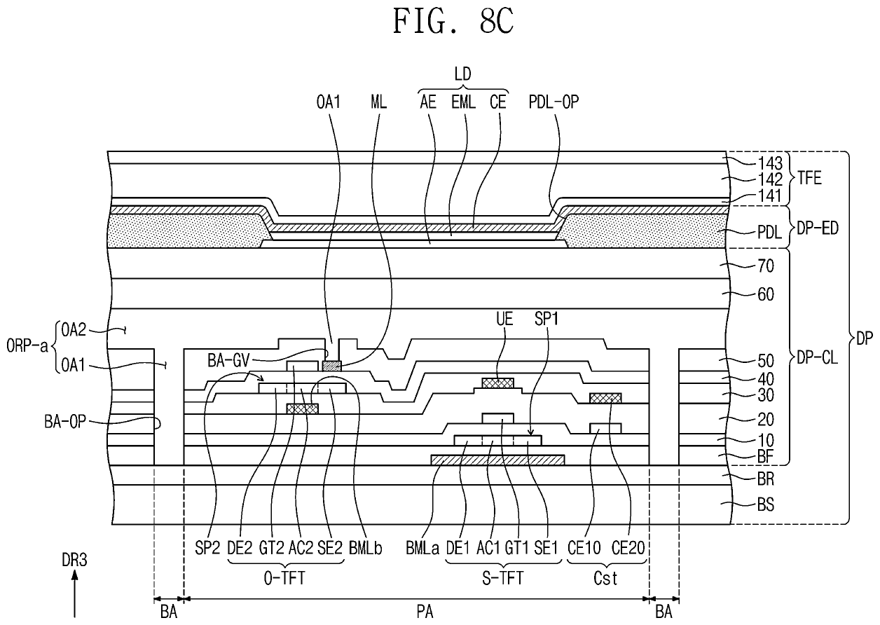

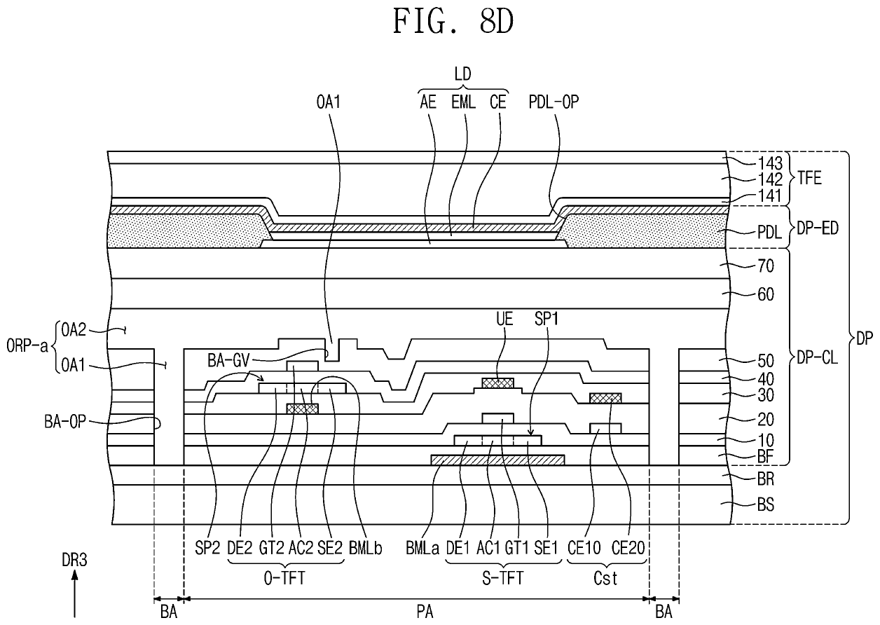

The circuit layer DP-CL may be disposed on the base layer BS. The circuit layer DP-CL may include an insulating layer, a semiconductor pattern, a conductive pattern, and a signal line. The display element layer DP-ED may be disposed on the circuit layer DP-CL. The display element layer DP-ED may include a light emitting element LD (see FIG. 8A) to be described below. For example, the light emitting element LD (see FIG. 8A) may include an organic light emitting material, an inorganic light emitting material, an organic-inorganic light emitting material, a quantum dot, a quantum rod, a micro-LED, or a nano-LED.

The encapsulation layer TFE may be disposed on the display element layer DP-ED. The encapsulation layer TFE may protect the display element layer DP-ED from foreign objects such as, for example, moisture, oxygen, and dust particles. The encapsulation layer TFE may include at least one inorganic layer. For example, the encapsulation layer TFE may include a structure in which a first encapsulation inorganic layer 141 (see FIG. 8A), an encapsulation organic layer 142 (see FIG. 8A), and a second encapsulation inorganic layer 143 (see FIG. 8A) are sequentially stacked on each other.

The input sensing layer ISL may be disposed on the display panel DP. The input sensing layer ISL may be directly disposed on the encapsulation layer TFE. Alternatively, an adhesive member may be interposed between the input sensing layer ISL and the display panel DP.

In the specification, when one component is directly disposed on another component, a third component is not interposed between the one component and the other component. In other words, when the one component is “directly disposed” on the other component, the one component makes “contact” with the other component.

The input sensing layer ISL may sense the external input, may change the sensed input into a specific input signal, and may provide the input signal to the display panel DP. For example, the input sensing layer ISL may be a touch sensing layer capable of sensing touch inputs. The input sensing layer ISL may recognize a direct touch by a user, an indirect touch by the user, a direct touch by an object, or an indirect touch by the object.

The input sensing layer ISL may sense at least one of a position or a strength (pressure) of a touch applied from the outside. The input sensing layer ISL may have various structures or may include various materials, but the present disclosure is not limited to any one embodiment. For example, the input sensing layer ISL may sense an external input in a capacitive manner. The display panel DP may receive the input signal from the input sensing layer ISL and may generate an image corresponding to the input signal.

Although not illustrated, the display module DM may further include an optical layer disposed on the display panel DP. The optical layer may be disposed on the display panel DP to control reflective light from the display panel DP by external light. The optical layer may include a polarizing plate or a color filter layer.

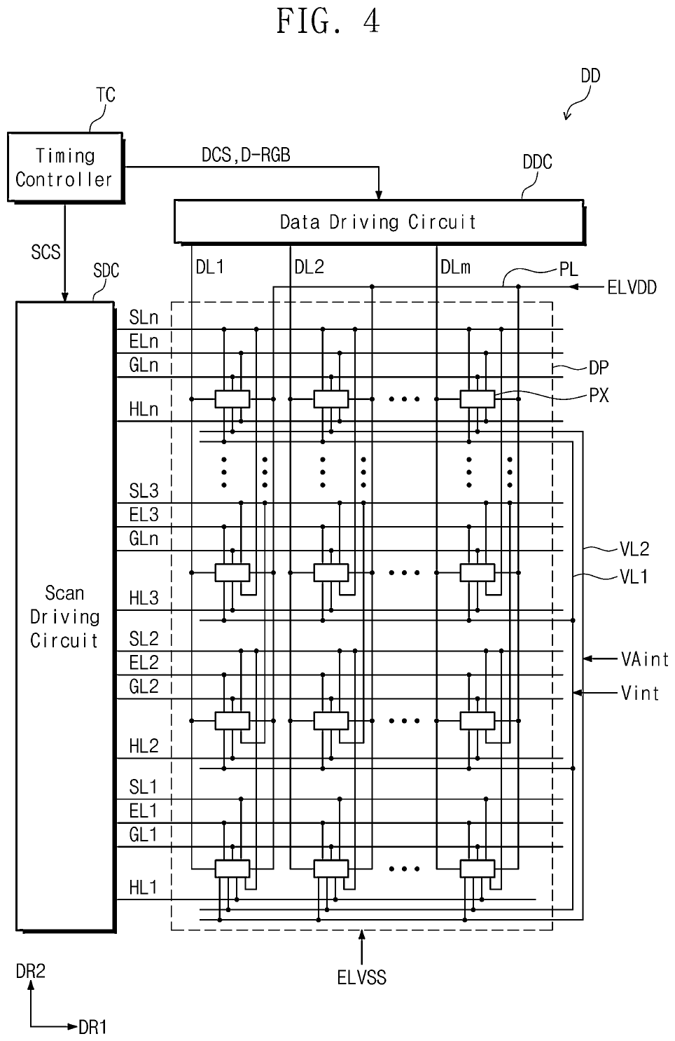

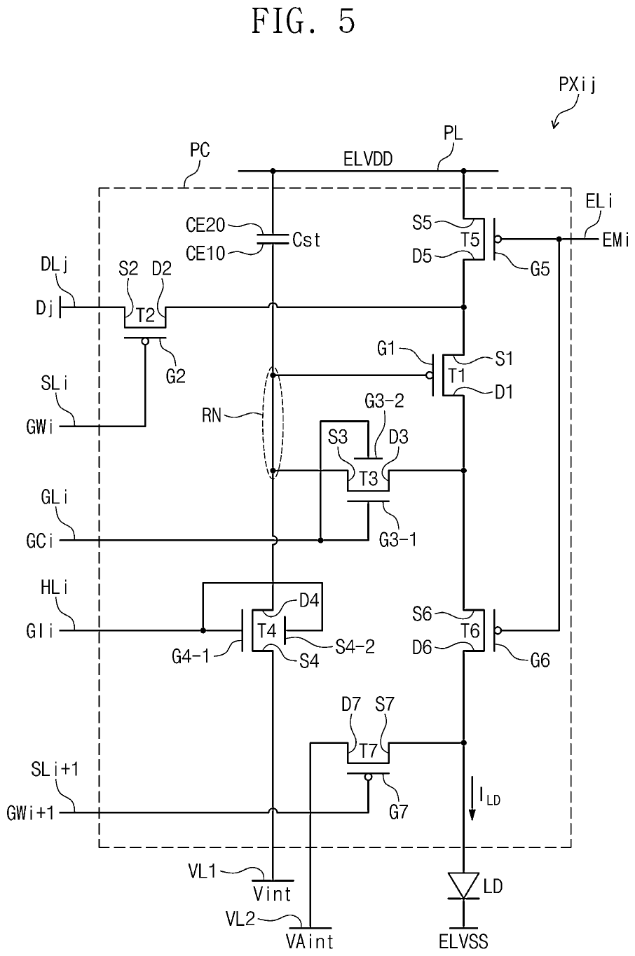

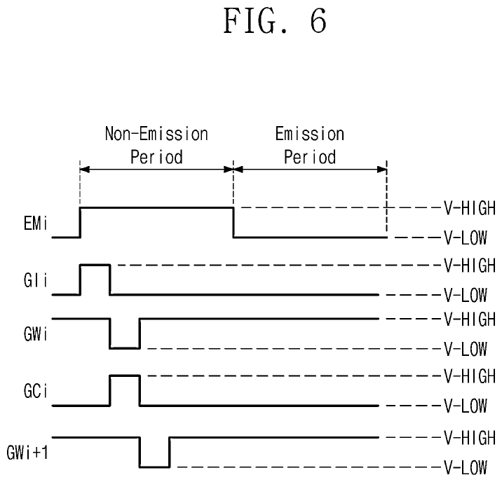

FIG. 4 is a block diagram of an embodiment of the display device DD according to aspects of the present disclosure. FIG. 5 is an equivalent circuit diagram of an embodiment of the pixel PX according to aspects of the present disclosure. FIG. 6 is a waveform diagram of an embodiment of a driving signal for driving the pixel PX according to aspects of the present disclosure.

Referring to FIG. 4, the display device DD may include the display panel DP, a timing controller TC, a scan driving circuit SDC, and the data driving circuit DDC. At least one of the timing controller TC, the scan driving circuit SDC, and the data driving circuit DDC may be provided in the form of a driving chip or may be directly formed on or integrated with the display panel DP.

The timing controller TC may receive input image signals and transform a data format of the input image signals to match an interface specification associated with the scan driving circuit SDC to generate image data D-RGB. The timing controller TC outputs the image data D-RGB and various control signals DCS and SCS.

The scan driving circuit SDC may receive the scan control signal SCS from the timing controller TC. The scan control signal SCS may include a vertical start signal for starting an operation of the scan driving circuit SDC, and a clock signal for determining an output timing of signals. The scan driving circuit SDC may generate a plurality of scan signals and sequentially output the scan signals to corresponding signal lines SL1 to SLn, GL1 to GLn, and HL1 to HLn. In some aspects, the scan driving circuit SDC may generate a plurality of light emitting control signals in response to the scan control signal SCS, and may output the light emitting control signals to corresponding a plurality of light emitting lines EL1 to ELn.

The data driving circuit DDC may receive the data control signal DCS and the image data D-RGB from the timing controller TC. The data driving circuit DDC may transform the image data D-RGB into data signals and may output the data signals to a plurality of data lines DL1 to DLm to be described later. The data signals may be analog voltages that respectively correspond to gray scale values of the image data D-RGB.

The signal lines in a plurality of groups may include a first group of the scan lines SL1 to SLn, a second group of the scan lines GL1 to GLn, a third group of the scan lines HL1 to HLn, the light emitting lines EL1 to ELn, the data lines DL1 to DLm, a first voltage line PL, a second voltage line VL1, and a third voltage line VL2. The first group of scan lines SL1 to SLn, the second group of scan lines GL1 to GLn, the third group of scan lines HL1 to HLn, and the light emitting lines EL1 to ELn may extend in the first direction DR1 and may be arranged in the second direction DR2 crossing the first direction DR1. The plurality of data lines DL1 to DLm may be insulated from the first group of scan lines SL1 to SLn, the second group of scan lines GL1 to GLn, the third group of scan lines HL1 to HLn, and the light emitting lines EL1 to ELn, while crossing the first group of scan lines SL1 to SLn, the second group of scan lines GL1 to GLn, the third group of scan lines HL1 to HLn, and the light emitting lines EL1 to ELn.

Each of the first voltage line PL, the second voltage line VL1, and the third voltage line VL2 may include at least one of components extending in the first direction DR1 and components extending in the second direction DR2. Each of the first voltage line PL, the second voltage line VL1, and the third voltage line VL2 may include components extending in the first direction DR1 and components extending in the second direction DR2. The structure and the shape of the first voltage line PL, the second voltage line VL1, and the third voltage line VL2 may be designed independently from each other.

Each of the plurality of pixels PX may be electrically connected to signal lines, which correspond to the pixels PX, of the above-described signal lines. The connection relationship between the pixels PX and the signal lines may be changed depending on the configuration of the driving circuit of the pixels PX.

The first voltage line PL may receive a first power supply voltage ELVDD. A second power supply voltage ELVSS may be applied to the display panel DP. The second power supply voltage ELVSS may have a level lower than a level of the first power supply voltage ELVDD.

The second voltage line VL1 may receive a first initialization voltage Vint. The first initialization voltage Vint may have a level lower than a level of the first power supply voltage ELVDD. The third voltage line VL2 may receive a second initialization voltage VAint. The second initialization voltage VAint may have a level lower than a level of the first power supply voltage ELVDD. The first initialization voltage Vint and the second initialization voltage VAint may be bias voltages having a specific level. The first initialization voltage Vint and the second initialization voltage VAint may have mutually different levels. The second initialization voltage VAint may have a level lower than a level of the first initialization voltage Vint. Descriptions herein of a voltage having a level lower than (or higher than) a level of another voltage may be referred to the voltage being less than (or greater than) the other voltage.

The plurality of pixels PX may include a plurality of pixel groups, each of which generates light of different colors from each other. For example, the plurality of pixels PX may include red pixels to generate red light, green pixels to generate green light, and blue pixels to generate blue light. The light emitting element of the red pixel, the light emitting element of the green pixel, and the light emitting element of the blue pixel may include light emitting layers formed of mutually different materials.

FIG. 5 illustrates a pixel PXij connected to an i-th scan line SLi, which is present in the first group, of the first group of scan lines SL1 to SLn, and connected to a j-th data line DLj of the plurality of data lines DL1 to DLm. The pixel PXij may include a pixel driving circuit PC (hereinafter, a pixel circuit) and the light emitting element LD.

Referring to FIG. 5, the pixel circuit PC may include first to seventh transistors T1, T2, T3, T4, T5, T6, and T7 and a capacitor Cst. The first transistor T1, the second transistor T2, and the fifth to seventh transistors T5, T6, and T7 may be P-type transistors, and the third transistor T3 and the fourth transistor T4 may be N-type transistors. However, the present disclosure is not limited thereto. For example, the first to seventh transistors T1, T2, T3, T4, T5, T6, and T7 may be any suitable combination of P-type transistors and N-type transistors supportive of aspects of the pixel circuit PC.

In the following description, an input region (or an input electrode) of an N-type transistor will be described as a drain (or a drain region), an input region of the P-type transistor will be described as a source (or a source electrode), an output region (or an output electrode) of the N-type transistor will be described as a source (or a source region), and an output region of the P-type transistor will be described as a drain (or a drain). In one or more embodiments, although not illustrated, at least one of the first to seventh transistors T1, T2, T3, T4, T5, T6, and T7 may be omitted.

For example, the first transistor T1, the second transistor T2, and the fifth to seventh transistors T5, T6, and T7 may be silicon transistors. The third transistor T3 and the fourth transistor T4 may be oxide transistors.

The first transistor T1 may be a driving transistor, and the second transistor T2 may be a switching transistor. The capacitor Cst may be electrically connected between the first voltage line PL to receive the first power supply voltage ELVDD and a reference node RN. The capacitor Cst may include a first electrode CE10 electrically connected to the reference node RN and a second electrode CE20 electrically connected to the first voltage line PL.

The first transistor T1 may be electrically connected between the first voltage line PL and an electrode (e.g., an anode) of the light emitting element LD. A source S1 of the first transistor T1 may be electrically connected to the first voltage line PL. In the present specification, the term “electrically connected between the transistor and the signal line or between the transistor and the transistor” refers to that “the source, drain, and gate of the transistor have an integral shape with the signal line or are connected through a connection electrode.” In some aspects, another transistor may be disposed or omitted between the source S1 of the first transistor T1 and the first voltage line PL.

A drain D1 of the first transistor T1 may be electrically connected to the anode of the light emitting element LD. For example, another transistor (e.g., transistor T6) may be disposed or omitted between the drain D1 of the first transistor T1 and the anode of the light emitting element LD. A gate G1 of the first transistor T1 may be electrically connected to the reference node RN.

The second transistor T2 may be electrically connected between the j-th data line DLj and the source S1 of the first transistor T1. A source S2 of the second transistor T2 may be electrically connected with the j-th data line DLj, and a drain D2 of the second transistor T2 may be electrically connected with the source S1 of the first transistor T1. A gate G2 of the second transistor T2 may be electrically connected with the i-th scan line in the first group.

The third transistor T3 may be electrically connected between the reference node RN and the drain D1 of the first transistor T1. A drain D3 of the third transistor T3 may be electrically connected to the drain D1 of the first transistor T1, and a source S3 of the third transistor T3 may be electrically connected to the reference node RN. Gates G3-1 and G3-2 of the third transistor T3 may be electrically connected to the i-th scan line Gli in the second group.

The fourth transistor T4 may be electrically connected between the reference node RN and the second voltage line VL1. A drain D4 of the fourth transistor T4 may be electrically connected to the reference node RN, and a source S4 of the fourth transistor T4 may be electrically connected to the second voltage line VL1. Gates G4-1 and G4-2 of the fourth transistor T4 may be electrically connected to the i-th scan line GLi in the third group.

Although FIG. 5 illustrates that the third transistor T3 and the fourth transistor T4 include a plurality of gates, the embodiment is not limited thereto. For example, at least one of the third transistor T3 and the fourth transistor T4 may include a single gate.

The fifth transistor T5 may be electrically connected between the first voltage line PL and the source S1 of the first transistor T1. A source S5 of the fifth transistor T5 may be electrically connected with the first voltage line PL, and a drain D5 of the fifth transistor T5 may be electrically connected to the source S1 of the first transistor T1. A gate G5 of the fifth transistor T5 may be electrically connected with the i-th light emitting line ELi.

The sixth transistor T6 may be electrically connected between the drain D1 of the first transistor T1 and the light emitting element LD. A source S6 of the sixth transistor T6 may be electrically connected with the drain D1 of the first transistor T1, and a drain D6 of the sixth transistor T6 may be electrically connected with an anode of the light emitting element LD. A gate G6 of the sixth transistor T6 may be electrically connected with the i-th light emitting line ELi. Alternatively, the gate G6 of the sixth transistor T6 may be connected to a different signal line from the gate G5 of the fifth transistor T5.

The seventh transistor T7 may be electrically connected between the drain D6 of the sixth transistor T6 and the third voltage line VL2. A source S7 of the seventh transistor T7 may be electrically connected with the drain D6 of the sixth transistor T6, and a drain D7 of the seventh transistor T7 may be electrically connected with the third voltage line VL2. A gate G7 of the seventh transistor T7 may be electrically connected with the (i+1)-th scan line SLi+1.

The operation of the pixel PXij will be described in more detail with reference to FIGS. 5 and 6. The display device DD may display an image for every frame period. During each of the frame periods, signal lines of the first group of scan lines SL1 to SLn, the second group of scan lines GL1 to GLn, the third group of scan lines HL1 to HLn, and the light emitting lines EL1 to ELn may be sequentially scanned. FIG. 6 illustrates a portion of any one frame period.

Referring to FIG. 6, each of the signals EMi, Gli, GWi, GCi, and GWi+1 may have a high level V-HIGH for a period(s) of time and may have a low level V-LOW for another period(s) of time. N-type transistors are turned on when the relevant signals have the high level V-HIGH, and P-type transistors may be turned on when the relevant signals have the low level V-LOW.

When a light emitting control signal EMi has the high level V-HIGH, the fifth transistor T5 and the sixth transistor T6 may be turned off. When the fifth transistor T5 and the sixth transistor T6 are turned off, a current path may not be formed between the first voltage line PL and the light emitting element LD. Accordingly, the relevant period may be defined as a non-emission period.

When the scan signal Gli having the high level V-HIGH is applied to the i-th scan line HLi in the third group, the fourth transistor T4 may be turned on. When the fourth transistor T4 is turned on, the reference node RN may be initialized by the first initialization voltage Vint. When the scan signal GWi having the low level V-LOW is applied to the i-th scan line SLi in the first group, and when the scan signal GCi having the high level V-HIGH is applied to the i-th scan line GLi of the second group, the second transistor T2 and the third transistor T3 may be turned on.

Since the reference node RN is initialized to the first initialization voltage Vint, the first transistor T1 may be turned on. When the first transistor T1 is turned on, a voltage corresponding to the data signal Dj (FIG. 4) is provided to the reference node RN. In this case, the capacitor Cst may store a voltage corresponding to the data signal Dj. The voltage corresponding to the data signal Dj may be a voltage reduced by a threshold voltage (Vth) of the first transistor T1 from the data signal Dj.

When the scan signal GWi+1 applied to the i+1th scan line SLi+1 in the first group has the low level V-LOW, the seventh transistor T7 may be turned on. As the seventh transistor T7 is turned on, the anode of the light emitting element LD is initialized to the second initialization voltage VAint. The parasitic capacitor of the light emitting element LD may be discharged.

When the light emitting control signal EMi has the low level V-LOW, the fifth transistor T5 and the sixth transistor T6 may be turned on. When the fifth transistor T5 is turned on, the first power supply voltage ELVDD may be provided to the first transistor T1. When the sixth transistor T6 is turned on, the first transistor T1 and the light emitting element LD may be electrically connected to each other. The light emitting element LD may generate light having brightness corresponding to an amount of current received.

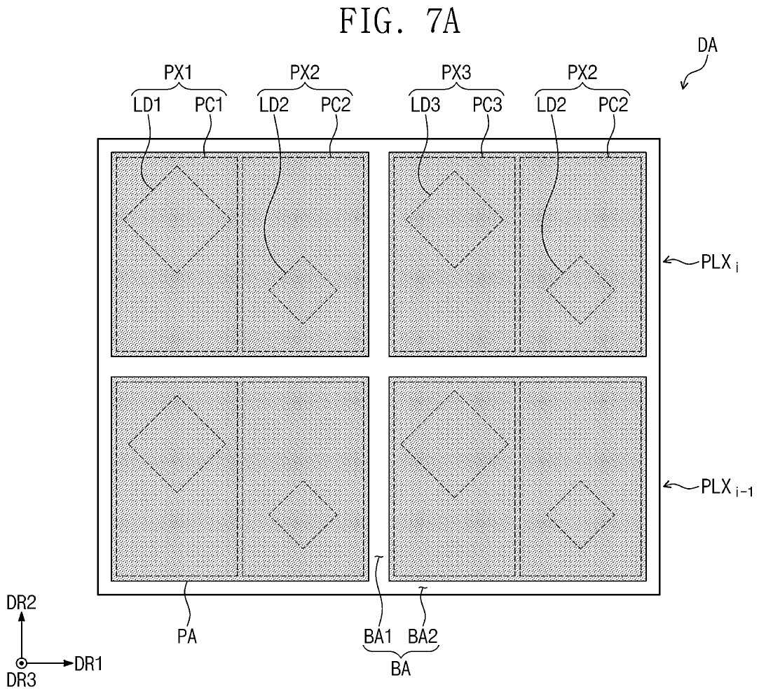

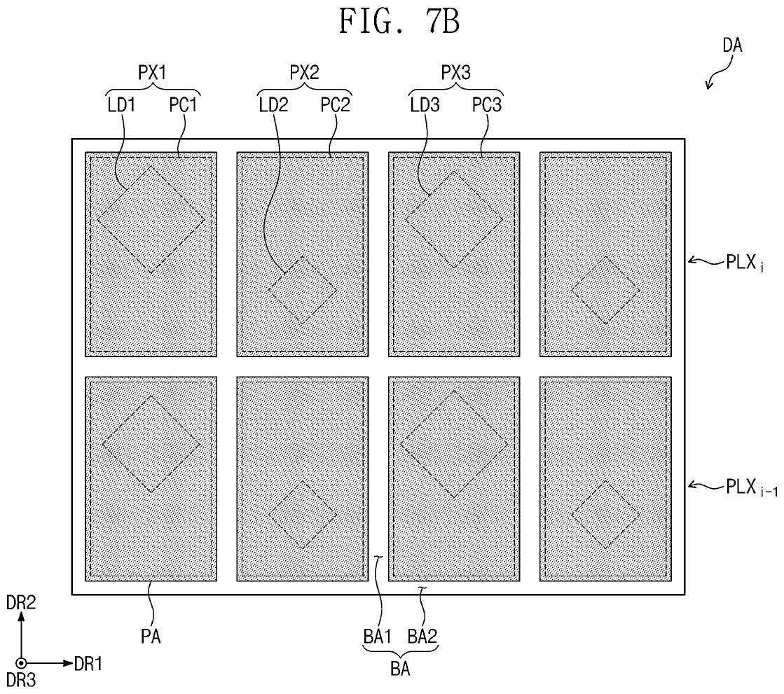

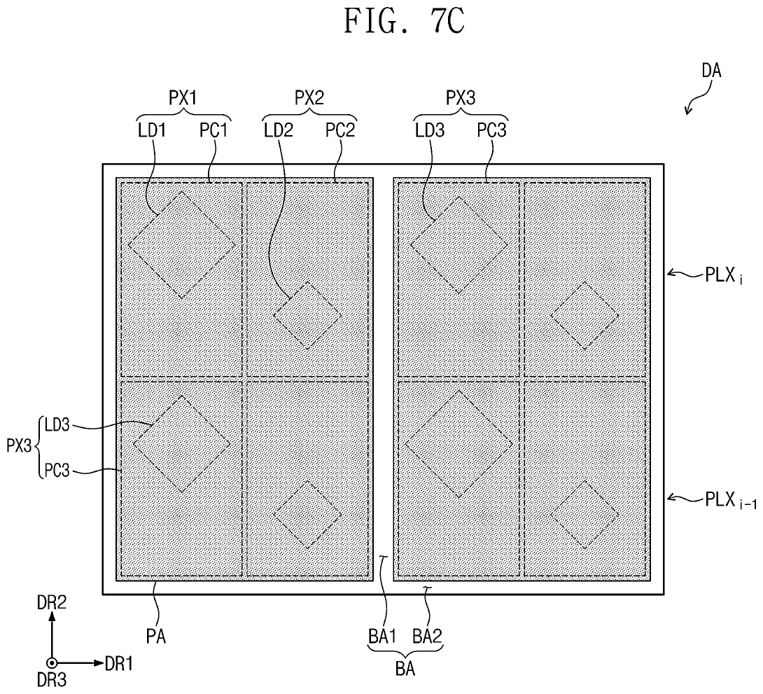

FIG. 7A is an enlarged plan view of an embodiment of a display panel, according to aspects of the present disclosure. In more detail, FIG. 7A is an enlarged view of the display region DA of the display panel DP.

FIG. 7A illustrates an enlarged view of two pixel rows PLXᵢ and PLXᵢ₋₁. The (i−1)-th pixel row PLXᵢ₋₁ may include a third color pixel PX3, a second color pixel PX2, a first color pixel PX1, and a second color pixel PX2 arranged in the first direction DR1. In the i-th pixel row PLXᵢ, the first color pixel PX1, the second color pixel PX2, the third color pixel P3, and the second color pixel P2 may be repeatedly disposed in the first direction DR1.

The (i−1)-th pixel row PLXᵢ₋₁ may include the third color pixel PX3, the second color pixel PX2, the first color pixel PX1, and the second color pixel PX2 arranged in the first direction DR1. The third color pixel PX3, the second color pixel PX2, the first color pixel PX1, and the second color pixel PX2 may be repeatedly disposed in the (i−1)-th pixel row PLXᵢ₋₁ in the first direction DR1. In some aspects, the first to third color pixels PX1, PX2, and PX3 in the pixel rows PLXᵢ and PLXᵢ₋₁ illustrated in FIG. 7A may be repeatedly arranged in the second direction DR2. For example, pixel row PLXᵢ and pixel row PLXᵢ₋₁ may be repeatedly disposed or arranged in the second direction DR2. In FIG. 7A, anodes of a first light emitting element LD1, a second light emitting element LD2, and a third light emitting element LD3 are shown as dotted lines. In the example illustrated at FIG. 7A, two light emitting elements (any two light emitting elements among the light emitting elements LD1, LD2, and LD3) are included in each pixel region PA.

The display region DA may include a plurality of pixel regions PA and a boundary region BA between the plurality of pixel regions PA. The boundary region BA may be disposed to be adjacent to at least a portion of each of the plurality of pixel regions PA. In an example, two adjacent color pixels among the first color pixel PX1, the second color pixel PX2, and the third color pixel PX3 may be surrounded by the boundary region BA. The boundary region BA may include a second boundary region BA2 extending in the first direction DR1 and a first boundary region BA1 extending in the second direction DR2.

Pixel circuits PC1, PC2, and PC3 of the first color pixel PX1, the second color pixel PX2, and the third color pixel PX3 may be disposed in the plurality of pixel regions PA, respectively. The pixel circuits PC1, PC2, and PC3 may be overlapped by the pixel regions PA. The pixel circuits PC1, PC2, and PC3 may be the same as the pixel circuit PC described with reference to FIG. 6. Although FIG. 7A illustrates that the pixel circuits PC1, PC2, and PC3 are substantially matched with the pixel region PA, the embodiment is not limited thereto. In the examples described herein, descriptions in which one component is “overlapped” with one component (or “overlapped” by one component) is not limited to the meaning that one component has the same shape and the same area as those of another component, when viewed in a plan view, but include the meaning that at least one of the shape and area of the one component differ from those of another component. For example, descriptions of a component described as “overlapping” with another component include instances in which the component fully or partially overlaps the other component (or is fully or partially overlapped by the other component).

FIGS. 7B and 7C are enlarged plan views of an embodiment of the display panel DP, according to aspects of the present disclosure. FIGS. 7B and 7C are plan views illustrating the display region DA of the display panel DP. FIGS. 7B and 7C illustrate examples in which the number of light emitting elements disposed in the pixel region PA differs compared with the display panel of FIG. 7A.

Referring to FIG. 7B, any one of the first color pixel PX1, the second color pixel PX2, and the third color pixel PX3 may be disposed in each pixel region PA, and each of the pixel regions PA may be surrounded by the boundary region BA. FIG. 7B illustrates that one pixel is disposed in each pixel region PA. In the example illustrated at FIG. 7B, the first color pixel PX1 and the second color pixel PX2 are spaced apart from each other, and the first boundary region BA1 is interposed between the first color pixel PX1 and the second color pixel PX2, which is different from FIG. 7A.

Referring to FIG. 7C, one first color pixel PX1, one third color pixel PX3, and two second color pixels PX2 may be disposed in a pixel region PA. Each of the pixel regions PA may be surrounded by the boundary region BA. In other words, FIG. 7C illustrates that four pixels are disposed in each pixel region PA. FIG. 7C illustrates that the pixels in the i-th pixel row PLXᵢ and the (i−1)-th pixel row PLXᵢ₋₁ constitute one pixel region PA. For example, pixels PX1 and PX2 in the i-th pixel row PLXi and pixels PX3 and PX2 in the (i−1)-th pixel row PLXᵢ₋₁ may constitute a pixel region PA.

FIG. 8A is a cross-sectional view of an embodiment of the display panel DP, according to aspects of the present disclosure. FIG. 8A illustrates the base layer BS, the circuit layer DP-CL, the display element layer DP-ED, and the encapsulation layer TFE of FIG. 3.

FIG. 8A illustrates a light emitting element LD, a silicon transistor S-TFT, and an oxide transistor O-TFT. In an example with reference to the equivalent circuit diagram illustrated in FIG. 5, the third and fourth transistors T3 and T4 among the first to seventh transistors T1, T2, T3, T4, T5, T6, and T7 may be oxide transistors O-TFT, and the remaining transistors T1, T2, T5, T6, and T7 may be silicon transistors S-TFT. Alternatively, the pixel circuit PC may include a single transistor type (e.g., one of the silicon transistor S-TFT and the oxide transistor O-TFT). For example, the first to seventh transistors T1, T2, T3, T4, T5, T6, and T7 may all be oxide transistors O-TFT, or the first to seventh transistors T1, T2, T3, T4, T5, T6, and T7 may all be silicon transistors S-TFT. In the following example description made with reference to FIG. 8A, the silicon transistor S-TFT will be described as the first transistor T1 of FIG. 5, and the oxide transistor O-TFT will be described as the third transistor T3 of FIG. 5.

Referring to FIG. 8A, a barrier layer BR may be disposed on the base layer BS. The barrier layer BR may prevent foreign substances from being introduced from the outside. The encapsulation layer TFE may include at least one inorganic layer. For example, the barrier layer BR may include a silicon oxide layer and/or a silicon nitride layer. In some aspects, the barrier layer BR may include a plurality of silicon oxide layers and the plurality of silicon nitride layers. The silicon oxide layers and the silicon nitride layers may be alternately stacked on each other.

A first shielding electrode BMLa may be disposed on the barrier layer BR. The first shielding electrode BMLa may include metal. The first shielding electrode BMLa may include molybdenum (Mo) a relatively high heat resistance, an alloy containing molybdenum (Mo), titanium (Ti), or an alloy containing titanium (Ti). Properties of molybdenum (Mo) support a substantial or excellent heat resistance compared to other materials.

The first shielding electrode BMLa may receive a bias voltage (e.g., first initialization voltage Vint, the second initialization voltage VAint) described herein. The first shielding electrode BMLa may receive first power supply voltage ELVDD described herein. The first shielding electrode BMLa may block electrical potential resulting from a polarization phenomenon from affecting the silicon transistor S-TFT. The first shielding electrode BMLa may block external light from reaching the silicon transistor S-TFT. In one or more embodiments, the first shielding electrode BMLa may be a floating electrode isolated from another electrode or a wire.

A buffer layer BF may be disposed on the barrier layer BR. The buffer layer BF may prevent metal atoms or impurities from diffusing from the base layer BS to a first semiconductor pattern SP1 disposed on the base layer BS. The buffer layer BF may include at least one inorganic layer. For example, the buffer layer BF may include a silicon oxide layer and/or a silicon nitride layer.

The first semiconductor pattern SP1 may be disposed on the buffer layer BF. The first semiconductor pattern SP1 may include a silicon semiconductor. For example, the silicon semiconductor may include amorphous silicon, or polycrystalline silicon. For example, the first semiconductor pattern SP1 may include low-temperature polysilicon.

FIG. 8A illustrates a portion of the first semiconductor pattern SP1, and the first semiconductor pattern SP1 may be further disposed in another region. The first semiconductor pattern SP1 may be disposed over the pixel region PA in accordance with one or more spacing or design rules. The first semiconductor pattern SP1 may have different electrical properties based on whether the first semiconductor pattern SP1 is doped. The first semiconductor pattern SP1 may include a first region and a second region, in which the first region has a higher conductivity and the second region has a lower conductivity. The first region may be doped with an N-type dopant or a P-type dopant. A P-type transistor may include a doping part doped with a P-type dopant, and an N-type transistor may include a doping part doped with an N-type dopant. The second region may be an undoped part or a part doped at a lower concentration than the first region. “Regions” of a semiconductor pattern as described herein may also be referred to as “areas,” “parts,” or “portions” of the semiconductor patter.

In an example, the conductivity of the first region is greater than the conductivity of the second region, and the first region may substantially serve as an electrode or a signal line. The second region may substantially correspond to a channel region of the transistor. The channel region may be referred to as an active region. In other words, a portion of the first semiconductor pattern SP1 may be a channel of a transistor, another portion of the first semiconductor pattern SP1 may be a source or a drain of the transistor, and a further portion of the first semiconductor pattern SP1 may be a connection electrode or a connection signal line.

A source region SE1, a channel region AC1, and a drain region DE1 of the silicon transistor S-TFT may be formed from the first semiconductor pattern SP1. The source region SE1 and the drain region DE1 may extend in opposite directions from the channel region AC1 when viewed in a cross-sectional view.

The first insulating layer 10 may be disposed on the buffer layer BF. The first insulating layer 10 may cover the first semiconductor pattern SP1. The first insulating layer 10 may be an inorganic layer. The first insulating layer 10 may include at least one of aluminum oxide, titanium oxide, silicon oxide, silicon nitride, silicon oxynitride, zirconium oxide, and hafnium oxide. The first insulating layer 10 may be a single-layered silicon oxide layer. Each of the first insulating layer 10 and the second to fifth insulating layers 20, 30, 40, and 50 to be described later may have a single-layer structure or multi-layer structure, and may include at least one of the above-described materials, but the present disclosure is not limited thereto.

A gate GT1 of the silicon transistor S-TFT is disposed on the first insulating layer 10. The gate GT1 may be a portion of the metal pattern. The gate GT1 may overlap the channel region AC1. In the process of doping the first semiconductor pattern SP1, the gate GT1 may be a mask. The gate GT1 may include molybdenum (Mo) which has a relatively high heat resistance, an alloy containing molybdenum (Mo), titanium (Ti), or the alloy containing titanium (Ti).

The first electrode CE10 of the storage capacitor Cst is disposed on the first insulating layer 10. The first electrode CE10 of the storage capacitor Cst may have the shape as the gate GT1 of the silicon transistor S-TFT. Although not illustrated, the first electrode CE10 of the storage capacitor Cst may be integrated with the gate GT1 of the silicon transistor S-TFT.

The second insulating layer 20 may be disposed on the first insulating layer 10, and the second insulating layer 20 may cover the gate GT1 of the silicon transistor S-TFT. An upper electrode UE overlapped with the gate GT1 may be disposed on the second insulating layer 20. The second electrode CE20 overlapped with the first electrode CE10 may be disposed on the second insulating layer 20. In some alternative aspects, different from the example illustrated in FIG. 8A, the second electrode CE20 may be integrated with the upper electrode UE. The second electrode CE20 and the upper electrode UE may include molybdenum (Mo) which has a relatively high heat resistance, an alloy containing molybdenum (Mo), titanium (Ti), or the alloy containing titanium (Ti).

A second shielding electrode BMLb may be disposed on the second insulating layer 20. The second shielding electrode BMLb may be disposed to correspond to a lower side of the oxide transistor O-TFT. In some alternative aspects, different from the illustrated example, the second shielding electrode BMLb may be omitted. For example, the first shielding electrode BMLa may extend to a lower portion of the oxide transistor O-TFT to replace the second shielding electrode BMLb. For examples in which the oxide transistor O-TFT includes two gates, the second shielding electrode BMLb may be a gate disposed at a lower portion of the oxide transistor O-TFT.

A third insulating layer 30 may be disposed on the second insulating layer 20. A second semiconductor pattern SP2 may be disposed on the third insulating layer 30. The second semiconductor pattern SP2 may include a channel region AC2 of the oxide transistor O-TFT.

A source region SE2, the channel region AC2, and a drain region DE2 of the oxide transistor O-TFT may be formed from the second semiconductor pattern SP2. The source region SE2 and the drain region DE2 may extend in opposite directions from the channel region AC2 when viewed in a cross-sectional view.

The second semiconductor pattern SP2 may include an oxide semiconductor. The second semiconductor pattern SP2 may include a transparent conductive oxide (TCO), such as, for example, indium tin oxide (ITO), indium zinc oxide (IZO), indium gallium zinc oxide (IGZO), zinc oxide (ZnOx), or indium oxide (In2O3). The zinc oxide (ZnOx) may be zinc oxide (ZnO) and/or zinc peroxide (ZnO₂).

The oxide semiconductor may include a plurality of regions classified according to whether a transparent conductive oxide is reduced. A region (hereinafter, referred to as the reduced region) in which the transparent conductive oxide is reduced, has greater conductivity than that of a region (hereinafter, referred to as the non-reduced region) in which the transparent conductive oxide is not reduced. The reduced region corresponds to or substantially serves as a source/drain or signal line of a transistor. The non-reduced region actually corresponds to an active region (or a channel region) of a transistor. In other words, a partial region of the second semiconductor pattern SP2 may be a semiconductor region of the transistor, another partial region of the second semiconductor pattern SP2 may be a source region/drain region of the transistor, and still another portion of the second semiconductor pattern SP2 may be a region for transmitting a signal.

The fourth insulating layer 40 may be disposed on the third insulating layer 30. The fourth insulating layer 40 may cover the second semiconductor pattern SP2. A gate GT2 of the oxide transistor O-TFT is disposed on the fourth insulating layer 40. The oxide transistor O-TFT may include two gates, and the two gates may be the second shielding electrode BMLb disposed on the second insulating layer 20 and the gate GT2 disposed on the fourth insulating layer 40. The second shielding electrode BMLb disposed on the second insulating layer 20 and the gate GT2 disposed on the fourth insulating layer 40 may be electrically connected to each other.

The gate GT2 of the oxide transistor O-TFT may be a portion of a metal pattern. The gate GT2 of the oxide transistor O-TFT may overlap the channel region AC2. The gate GT2 may include molybdenum (Mo) which has a relatively high heat resistance, an alloy containing molybdenum (Mo), titanium (Ti), and/or the alloy containing titanium (Ti). For example, the gate GT2 may include a titanium layer and a molybdenum layer disposed above the titanium layer.

The fifth insulating layer 50 may be disposed on the fourth insulating layer 40, and the fifth insulating layer 50 may cover the gate GT2. Each of the first to fifth insulating layers 10, 20, 30, 40, and 50 may include an inorganic layer.

Organic insulating layers 60 and 70 may be disposed on the fifth insulating layer 50. The first organic insulating layer 60 may be disposed on the fifth insulating layer 50, and the second organic insulating layer 70 may be disposed on the first organic insulating layer 60.

The first organic insulating layer 60 may remove the step difference of the fifth insulating layer 50 disposed under the first organic insulating layer 60 and may form a flat top surface. The first organic insulating layer 60 and the base layer BS may completely overlap.

In an example, each of the first organic insulating layer 60 and the second organic insulating layer 70 may include general purpose polymers such as, for example, benzocyclobutene (BCB), polyimide, hexamethyldisiloxane (HMDSO), polymethylmethacrylate (PMMA), or polystyrene (PS); a polymer derivative having a phenolic group; an acrylic polymer; an imide-based polymer, an acryl ether polymer; an amide-based polymer, a fluorine-based polymer; a p-xylene-based polymer; a vinyl alcohol-based polymer; or the blend thereof.

A first electrode AE of the light emitting element LD may be disposed on the second organic insulating layer 70. The light emitting element LD may include the first electrode AE, a second electrode CE on the first electrode AE, and a light emitting layer EML interposed between the first electrode AE and the second electrode CE. The second electrode CE may be provided on the first to third light emitting elements LD1, LD2, and LD3 illustrated in FIGS. 7A to 7C. The first electrode AE and the light emitting layer EML may be provided on each of the first to third light emitting elements LD1, LD2, and LD3.

The first electrode AE may be an anode or a cathode. The first electrode AE may be a transparent electrode, a translucent electrode, or a reflective electrode. The first electrode AE may include a reflective layer formed of Ag, Mg, Al, Pt, Pd, Au, Ni, Nd, Ir, Cr, or a compound thereof, and a transparent or translucent electrode layer formed on the reflective layer. The transparent or translucent electrode layer may include at least one selected from the group consisting of indium tin oxide (ITO), indium zinc oxide (IZO), indium gallium zinc oxide (IGZO), zinc oxide (ZnOx) or indium oxide (In2O3), and aluminum-doped zinc oxide (AZO). For example, the first electrode AE may include a three-layer structure of ITO/Ag/ITO, but the present disclosure is not limited thereto.

A pixel defining layer PDL may be disposed on the second organic insulating layer 70. The pixel defining layer PDL may have a transparent property or a property of absorbing light. For example, the pixel defining layer PDL may include a black coloring agent and absorb light. The black coloring agent may include a black dye and a black pigment. The black coloring agent may include metal, such as, for example, carbon black, and chromium, or an oxide thereof. The pixel defining layer PDL may correspond to a shielding pattern having light blocking characteristics.

The pixel defining layer PDL may cover a portion of the first electrode AE. For example, a pixel opening PDL-OP exposing a portion of the first electrode AE may be defined in the pixel defining layer PDL. The pixel defining layer PDL may increase a distance between the edge of the first electrode AE and the second electrode CE, in the thickness direction DR3. In the thickness direction DR3, the edge of the first electrode AE and the second electrode CE may be spaced apart with the pixel defining layer PDL interposed therebetween. Accordingly, the pixel defining layer PDL may prevent an arc from occurring at the edge of the first electrode AE.

For example, the light emitting element LD (see FIG. 8A) may include an organic light emitting material, an inorganic light emitting material, an organic-inorganic light emitting material, a quantum dot, a quantum rod, a micro-LED, or a nano-LED. The light emitting layer EML may be disposed in the pixel opening PDL-OP. In an example, the light emitting layer EML may include a fluorescent or phosphorescent material,

The second electrode CE may be a cathode or an anode, but the present disclosure is not limited thereto. For example, when the first electrode AE is an anode, the second electrode CE may be a cathode. When the first electrode AE is a cathode, the second electrode CE may be an anode. The second electrode CE may be disposed in the form of a common electrode. The second electrode CE may be referred to as a common electrode. Each of the second electrode CE may include at least one selected from Ag, Mg, Cu, Al, Pt, Pd, Au, Ni, Nd, Ir, Cr, Li, Ca, LiF, Mo, Ti, W, In, Sn, and Zn, a compound of at least two materials selected from the above materials, a mixture of at least two materials selected from the above materials, or an oxide thereof.

Although not illustrated, at least one of a hole transport layer, a hole injection layer, and an electron blocking layer may be interposed between the first electrode AE and the light emitting layer EML. At least one of an electron transport layer, an electron injection layer, and a hole blocking layer may be interposed between the light emitting layer EML and the second electrode CE.

The buffer layer BF and the first to fifth insulating layers 10, 20, 30, 40, and 50 may be defined in the form of a stack structure of an inorganic material. An opening BA-OP may be defined in the stack structure (or laminated structure) of the inorganic material. The opening BA-OP may correspond to the boundary region BA described with reference to FIGS. 7A to 7C.

The stack structure of the inorganic material may be divided into a plurality of islands to correspond to the plurality of pixels PX1, PX2, and PX3 illustrated in FIGS. 7A to 7C. Each of the plurality of islands may include at least one pixel region PA and the boundary region BA adjacent to the at least one pixel region PA. The plurality of islands may disperse forces associated with an external impact, which may thereby prevent the stack structure of the inorganic material from cracking due to external impact.

An organic layer ORP may be disposed to fill the opening BA-OP. The opening BA-OP may be formed while passing from a top surface to a bottom surface of each of the buffer layer BF and the first to fifth insulating layers 10, 20, 30, 40, and 50. That is, the opening BA-OP may be formed to penetrate all of the buffer layer BF and the first to fifth insulating layers 10, 20, 30, 40, and 50. The opening BA-OP may expose one surface of a component disposed under the buffer layer BF. The opening BA-OP may expose a top surface BR_UF of the barrier layer BR. Accordingly, for example, the bottom surface of the organic layer ORP may make contact with the barrier layer BR disposed under the buffer layer BF, and the top surface of the organic layer ORP may make contact with the first organic insulating layer 60 disposed on the fifth insulating layer 50. The first organic insulating layer 60 may cover the organic layer ORP. The first organic insulating layer 60 may make contact with the organic layer ORP and the fifth insulating layer 50.

However, the present disclosure is not limited thereto. As the depth of the opening BA-OP is variously changed in the thickness direction DR3, various components may make contact with the bottom surface of the organic layer ORP filling the opening BA-OP and disposed in the opening BA-OP. The bottom surface of the organic layer ORP may make contact with at least one of the first to third insulating layers 10, 20, and 30. For example, the bottom surface of the organic layer ORP may make contact with any one insulating layer of the first to third insulating layers 10, 20, and 30 in one region of the boundary region BA, and the bottom surface of the organic layer ORP may make contact with another insulating layer which is except for the any one insulating layer, of the first to third insulating layers 10, 20, and 30 in another region of the boundary region BA.

According to an embodiment, a groove BA-GV may be defined in the fifth insulating layer 50 covering the gate GT2 of the oxide transistor O-TFT. The groove BA-GV may be overlapped by the second semiconductor pattern SP2. The groove BA-GV may be spaced apart from the opening BA-OP in a direction perpendicular to the thickness direction DR3.

The groove BA-GV may be formed through a portion of the fifth insulating layer 50. For example, the groove BA-GV may pass through a top surface 50_UF of the fifth insulating layer 50, without passing through a bottom surface 50_DF of the fifth insulating layer 50. The opening BA-OP may pass through the top surface 50_UF of the fifth insulating layer 50 and the bottom surface 50_DF of the fifth insulating layer 50. Accordingly, a depth DH1 of the opening BA-OP may be larger than a depth DH2 of the groove BA-GV in the thickness direction DR3.

The groove BA-GV may be spaced apart from the bottom surface 50_DF of the fifth insulating layer 50. The groove BA-GV may be formed by etching a portion (e.g., an upper portion) of the fifth insulating layer 50 in the thickness direction DR3, without etching other portions (e.g., lower portions) of the fifth insulating layer 50. A metal layer ML to be described below may prevent a lower portion of the fifth insulating layer 50 and the fourth insulating layer 40 from being etched.

The formed groove BA-GV may prevent the stack structure from cracking due to external impact. The organic layer ORP may be disposed in the groove BA-GV.

If the groove is formed by performing an etching process from the top surface 50_UF to the bottom surface 50_DF of the fifth insulating layer 50 and by performing an etching process to the fourth insulating layer 40 disposed under the fifth insulating layer 50, excessive dehydrogenation may be generated through the groove. A method for manufacturing a display panel including a silicon semiconductor includes a dehydrogenation process, and the excessive dehydrogenation causes the deterioration in the characteristic of the transistor. The excessive dehydrogenation shifts the threshold voltage of the transistor to degrade the reliability of the display panel. In contrast, methods described herein may include forming the groove by etching a portion (e.g., an upper portion, without etching lower portions) of the fifth insulating layer 50, which may prevent the excessive dehydrogenation. Therefore, according to an embodiment, the display panel DP may have increased reliability. The display panel DP may further include the metal layer ML.

According to an embodiment, the metal layer ML may be disposed at the same layer as the gate GT2 of the oxide transistor O-TFT. The metal layer ML may be disposed on the second semiconductor pattern SP2. The metal layer ML may be overlapped by the second semiconductor pattern SP2, when viewed in a plan view. The metal layer ML may be directly disposed on the fourth insulating layer 40 covering the second semiconductor pattern SP2. The metal layer ML may be an etch stopper which prevents the fourth insulating layer 40 from being etched.

A surface M_UF (that is, a top surface) of the metal layer ML may be exposed by the groove BA-GV. Accordingly, the metal layer ML may make contact with the organic layer ORP. The metal layer ML may be formed of metal which is resistant to dry-etching. For example, the metal layer ML may include at least one of aluminum (Al), molybdenum (Mo), titanium (Ti), and indium gallium zinc oxide (IGZO).

In one or more embodiments, although not illustrated, the metal layer ML may be disposed on the upper portion of the first semiconductor pattern SP1. Although not illustrated, the metal layer ML may be disposed to be overlapped with the first semiconductor pattern SP1 when viewed in a plan view to prevent an insulating layer (e.g., at least one of the first to fifth insulating layers 10 to 50) adjacent to the first semiconductor pattern SP1 from being etched.

FIGS. 8B to 8D are cross-sectional views according to an embodiment of the present disclosure. In the following description made with reference to FIGS. 8B to 8D, repeated descriptions made with reference to FIGS. 1A to 8A will be omitted to avoid redundancy. The following descriptions will be made while focusing on the differences.

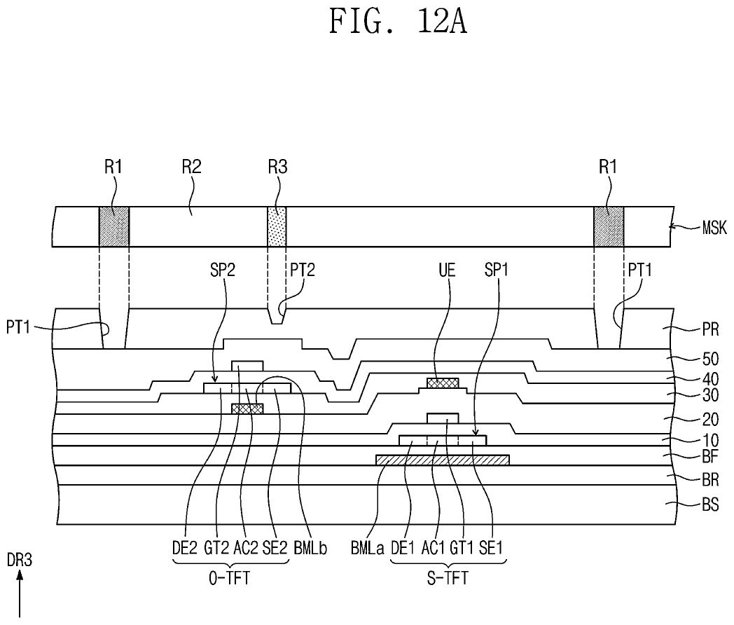

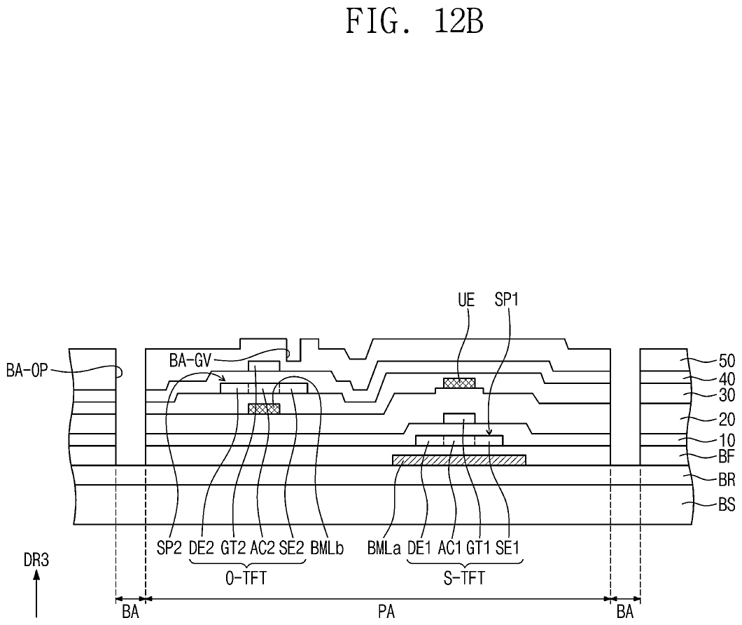

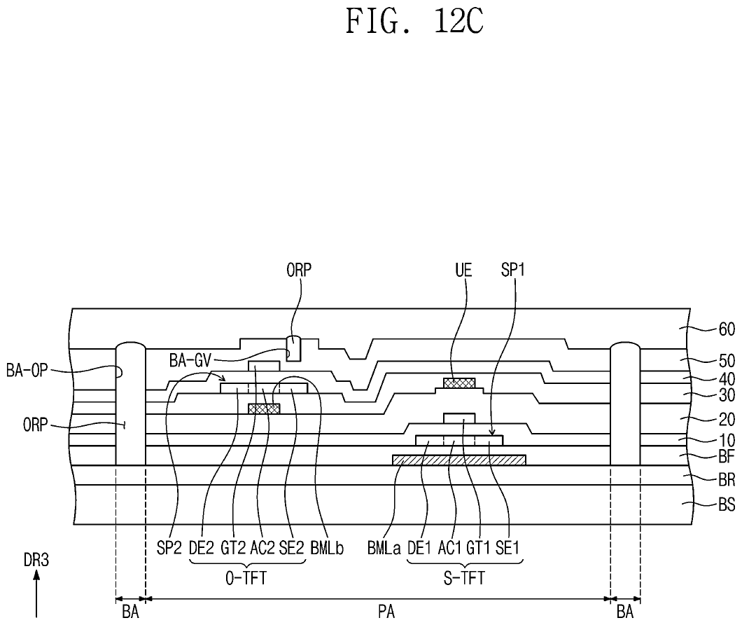

When compared to FIG. 8A, a difference is made in that the metal layer ML is absent in FIG. 8B. The groove BA-GV illustrated in FIG. 8B may be formed by etching a portion (e.g., an upper portion, without etching lower portions) of the fifth insulating layer 50. The groove BA-GV of FIG. 8B may be formed by providing a half tone mask MSK (see FIG. 12A) in a method for manufacturing the display panel according to an embodiment to be described later. In some aspects, through the use of the half tone mask MSK (see FIG. 12A) during manufacturing of the display panel, a portion of the fifth insulating layer 50 (e.g., an upper portion and not lower portions) is etched to form the groove BA-GV. According to an embodiment, the groove formed by etching a portion (e.g., an upper portion, without etching lower portions) of the fifth insulating layer 50 may prevent the excessive dehydrogenation. Therefore, according to an embodiment, the display panel DP may have increased reliability.

When compared to FIG. 8A, FIG. 8C differs in that the organic layer ORP-a includes the second region OA2 perpendicular to the thickness direction DR3. The description made with reference to the metal layer ML in FIG. 8A will be identically applied to the metal layer ML illustrated in FIG. 8C.

In one or more alternative embodiments, the organic layer ORP-a of FIG. 8C may omit the second region OA2, and the organic layer ORP illustrated in FIG. 8A may be substituted. The organic layer ORP-a may include a first region OA1 parallel to the thickness direction DR3 and the second region OA2 perpendicular to the thickness direction DR3. The first region OA1 may be a part filling the opening BA-OP corresponding to the boundary region BA. The first region OA1 may be a part filling the groove BA-GV. The second region OA2 may extend from the first region OA1, and the second region OA2 and the base layer BS may completely overlap. In the organic layer ORP-a, the second region OA2 and the first region OA1 may have an integral shape. The second region OA2 may remove a step difference between the first to fifth insulating layers 10, 20, 30, 40, and 50 disposed below and form a flat top surface. The first organic insulating layer 60 may be disposed on the second region OA2.

When compared to FIG. 8B, FIG. 8D differs in that the organic layer ORP-a includes the second region OA2 perpendicular to the thickness direction DR3. In one or more alternative embodiments, the organic layer ORP-a of FIG. 8D may omit the second region OA2, and the organic layer ORP illustrated in FIG. 8B may be substituted. The description made with reference to the organic layer ORP-a in FIG. 8C will be identically applied to the organic layer ORP-a illustrated in FIG. 8D. The description made with reference to the groove BA-GV in FIG. 8B will be identically applied to the groove BA-GV illustrated in FIG. 8D.

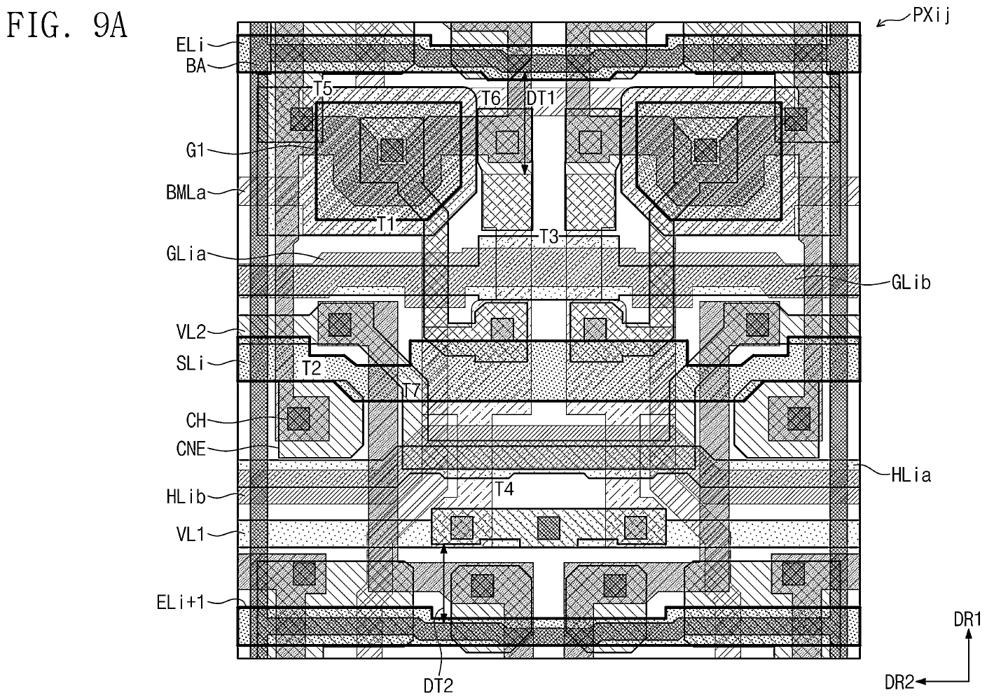

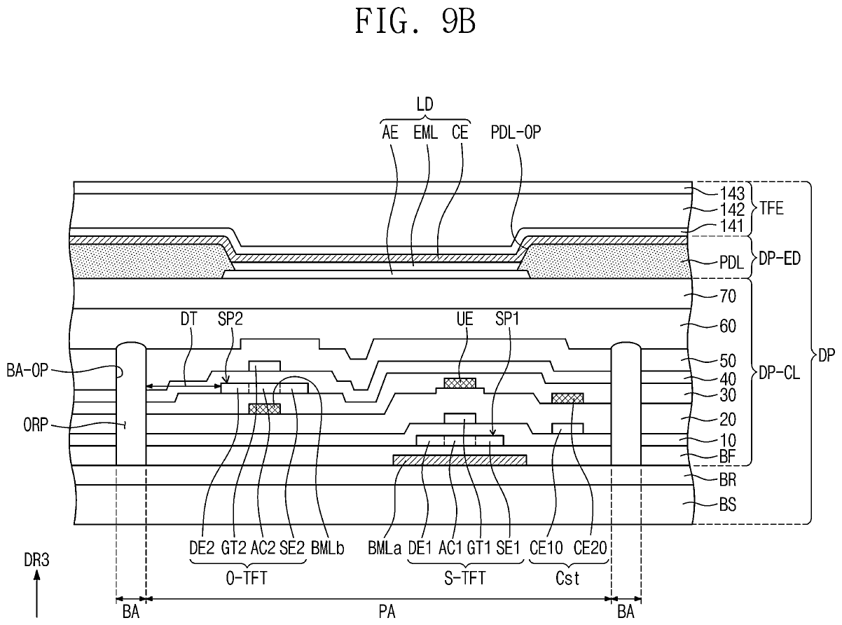

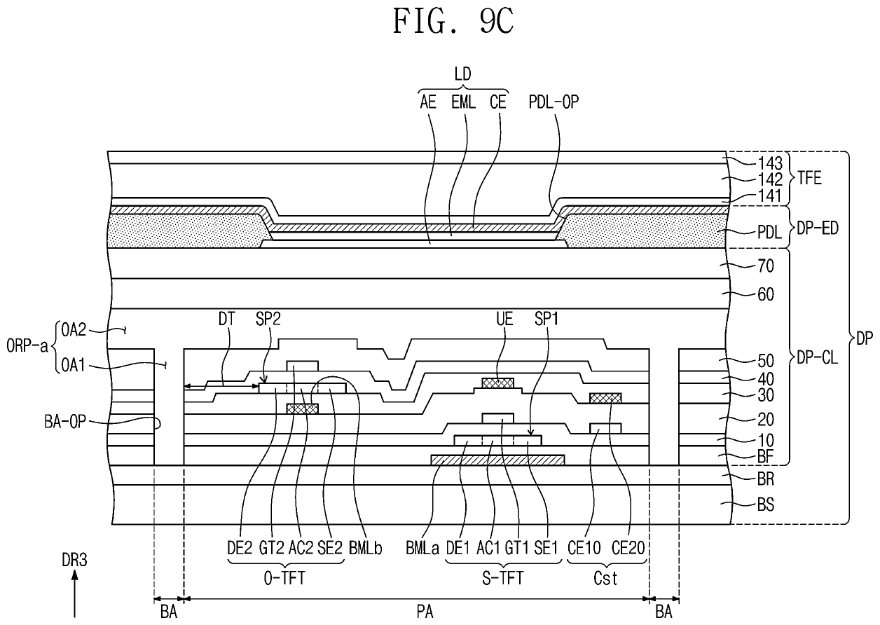

FIGS. 9A to 9C illustrate an embodiment including aspects similar or different from FIGS. 8A to 8D. In the following description made with reference to FIGS. 9A to 9C, repeated descriptions made with reference to FIGS. 1A to 8D will be omitted to avoid redundancy. The following descriptions will be made while focusing on the differences.

FIG. 9A is a plan view illustrating some components of a pixel PXij, a contact hole CH, and a connection electrode CNE described with reference to FIG. 6. The contact hole CH and the connection electrode CNE may electrically connect the components of the pixel PXij to the signal line. The contact hole CH may be formed in the same step as that of the opening BA-OP (e.g., during the formation of the opening BA-OP) (see FIG. 9B).

FIG. 9A illustrates the first to seventh transistors T1, T2, T3, T4, T5, T6, and T7 among the components of the pixel PXij, the i-th scan line SLi in the first group, scan lines GLia and Glib in the second group, scan lines HLia and HLib in the third group, the i-th light emission line ELi, the second voltage line VL1, and the third voltage line VL2. The connection relationship between the components of the pixel PXij of FIG. 9A are provided for illustrative purposes, and the embodiment is not limited thereto. FIG. 9A illustrates the (i+1)-th light emission line ELi+1, which is a component of the pixel PXi+1j.

As illustrated in FIG. 9A, the first sub-scan line GLia and the second sub-scan line Glib are disposed as the scan lines GLia and GLib in the second group, at mutually different layers and overlapped with each other when viewed in a plan view. The first sub-scan line GLia and the second sub-scan line Glib are electrically connected to each other and receive the same signal. In other words, the scan lines GL1 to GLn (see FIG. 4) in the second group may be wires at double layers to receive the same signal. However, the embodiment is not limited thereto, and any one of the first sub-scan line GLia and the second sub-scan line Glib may be omitted.

As illustrated in FIG. 9A, the third sub-scan line HLia and the fourth sub-scan line HLib are disposed as the scan lines HLia and HLib in the third group, at mutually different layers and overlapped with each other when viewed in a plan view. The third sub-scan line HLia and the fourth sub-scan line HLib are electrically connected to each other and receive the same signal. In other words, the scan lines HL1 to HLn (see FIG. 4) in the third group may be wires at double layers to receive the same signal. However, the embodiment is not limited thereto, and any one of the third sub-scan line HLia and the fourth sub-scan line HLib may be omitted.

According to an embodiment, a first distance DT1 between the third transistor T3 and the boundary region BA may be in the range of 5 μm to 70 μm. A second distance DT2 between the fourth transistor T4 and the boundary region BA may be in the range of 5 μm to 70 μm. The first and second distances DT1 and DT2 may be linear distances when viewed in a plan view perpendicular to the thickness direction DR3. The first and second distances DT1 and DT2 may be the shortest distance from the edges of the transistors T3 and T4 to the boundary region BA. The third and fourth transistors T3 and T4 may be oxide transistors O-TFT (see FIG. 9B). The oxide transistors O-TFT (see FIG. 9B) may be formed from the second semiconductor pattern SP2 (see FIG. 9B).

FIGS. 9B and 9C are cross-sectional views illustrating an embodiment of the display panel DP according to aspects of the present disclosure. Referring to FIG. 9B, a distance DT between the second semiconductor pattern SP2 and the opening BA-OP may be in the range of 5 μm to 70 μm. The distance DT illustrated in FIG. 9B may correspond to at least one of the first and second distances DT1 and DT2 illustrated in FIG. 9A.

Referring to FIGS. 9A and 9B, the third and fourth transistors T3 and T4 formed from the second semiconductor pattern SP2 may be non-overlapping with the boundary region BA. Accordingly, the openings BA-OP (see FIG. 9B) corresponding to the boundary region BA may not be formed at an upper portion of the third and fourth transistors T3 and T4, and the openings BA-OP (see FIG. 9B) may be non-overlapping with the third and fourth transistors T3 and T4. Accordingly, excessive dehydrogenation may be prevented so as to provide a display panel DP having increased reliability. In some techniques, when an opening overlapped with the second semiconductor pattern SP2 is formed, the fourth insulating layer 40 covering the second semiconductor pattern is etched. Accordingly, excessive dehydrogenation is caused, and thus the reliability of the display panel is reduced. In contrast, according to an embodiment, the opening BA-OP corresponding to the second semiconductor pattern SP2 and the boundary region BA is formed in accordance with the example distance ranges described herein, and the display panel DP may have increased reliability.

When compared to FIG. 9B, a difference is made in that the organic layer ORP-a includes the second region OA2 as illustrated in FIG. 9C. In one or more alternative embodiments, the organic layer ORP-a may omit the second region OA2, and the organic layer ORP illustrated in FIG. 9B may be substituted. The description made with reference to FIG. 9C will be identically applied to the organic layer ORP-a illustrated in FIG. 8B.

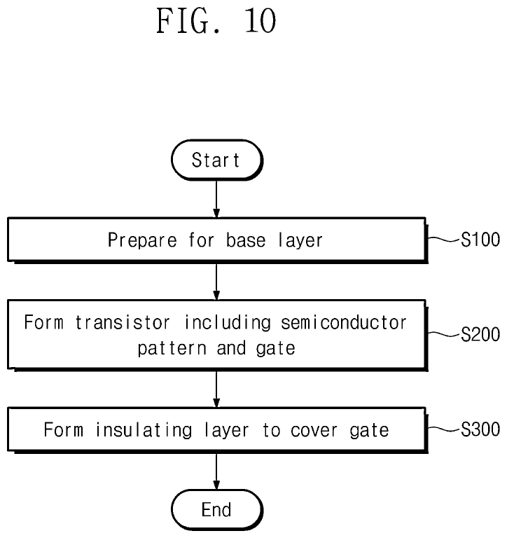

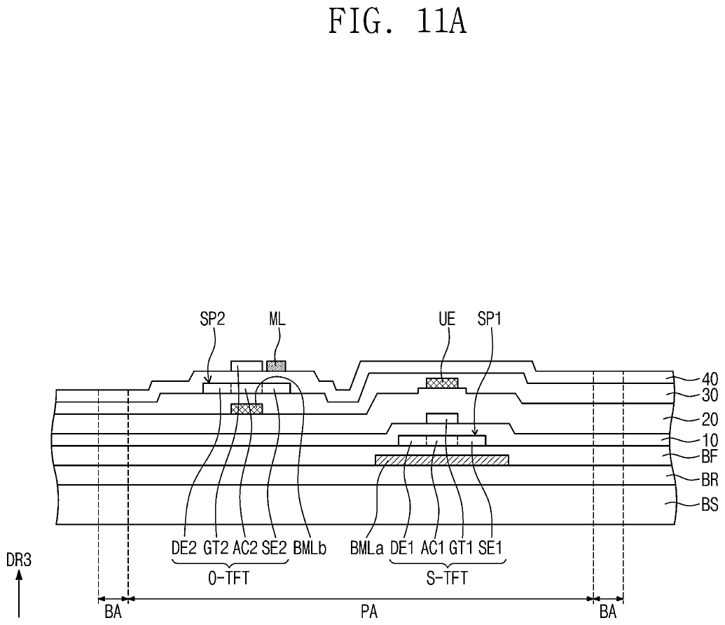

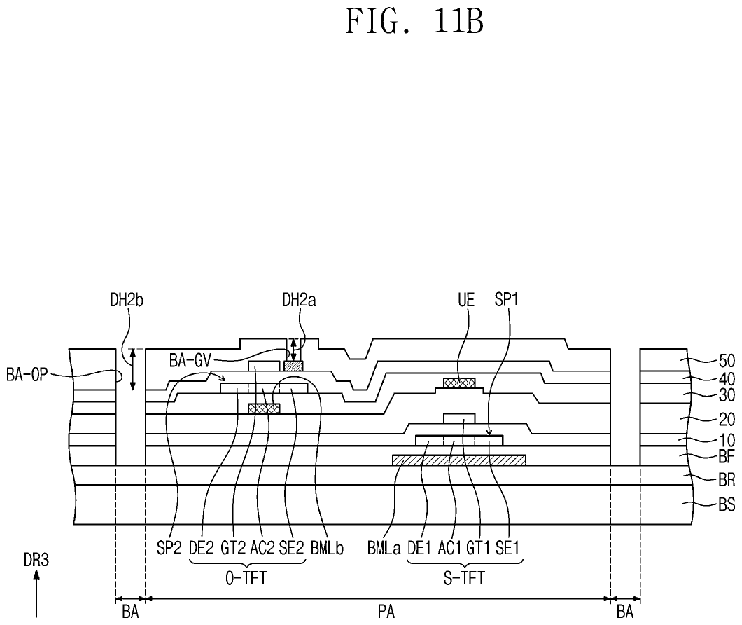

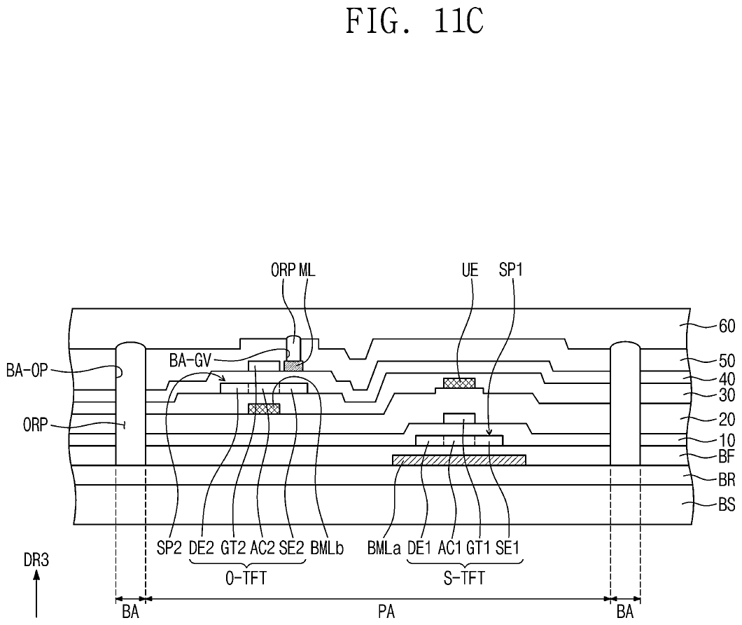

According to an embodiment, the display panel may be manufactured through the method for manufacturing the display panel. FIG. 10 is a flowchart illustrating the method for manufacturing the display panel according to an embodiment. FIGS. 11A to 12C are views schematically illustrating steps of manufacturing a display panel according to one or more embodiments. In the following description made with reference to FIGS. 10 to 12C, repeated descriptions made with reference to FIGS. 1 to 9C will be omitted to avoid redundancy. The following descriptions will be made while focusing on the differences.

Referring to FIG. 10, according to an embodiment, the method for manufacturing the display panel may include the steps of preparing a base layer (S100), forming a transistor including a semiconductor pattern and a gate (S200), and forming an insulating layer to cover the gate (S300). Referring to FIG. 11A, the base layer BS may include the pixel region PA and the boundary region BA. The silicon transistor S-TFT and the oxide transistor O-TFT may be disposed in the pixel region PA. The forming of the oxide transistor O-TFT may include forming the second semiconductor pattern SP2 and forming the gate GT2. The second semiconductor pattern SP2 may include an oxide semiconductor.

According to an embodiment, the method for manufacturing the display panel may further include forming the metal layer ML between forming the oxide transistor O-TFT and forming the fifth insulating layer 50 to cover the gate GT2. The metal layer ML may be formed of metal which is not dry-etched. For example, the metal layer ML may include at least one of aluminum (Al), molybdenum (Mo), titanium (Ti), and indium gallium zinc oxide (IGZO). The metal layer ML may be formed on the fourth insulating layer 40. The metal layer ML may be overlapped by the second semiconductor pattern SP2. The metal layer ML may be formed in the same step as that of the gate GT2 of the oxide transistor O-TFT. However, the present disclosure is provided for illustrative purposes, and the embodiment is not limited thereto. The fifth insulating layer 50 may be formed after forming the metal layer ML.

Referring to FIG. 11B, the opening BA-OP may be formed to correspond to the boundary region BA and the groove BA-GV may be formed in the metal layer ML. As the first to fifth insulating layers 10 to 50 are etched, the opening BA-OP may be formed and a portion of the fifth insulating layer 50 is etched to form the groove BA-GV. A first etching depth DH2a for forming the groove BA-GV in the fifth insulating layer 5 may be less than a second etching depth DH2b for forming the opening BA-OP0. The first and second etching depths DH2a and DH2b may be etching depths in the thickness direction DR3. The first etching depth DH2a may be an etching depth of a portion to form the groove BA-GV, which is formed by passing the top surface 50_UF of the fifth insulating layer 50 without passing through the bottom surface 50_DF of the fifth insulating layer 50. The second etching depth DH2b may be an etching depth of a portion to form the opening BA-OP formed by boring the fifth insulating layer 50, from top surface 50_UF to the bottom surface 50_DF of the fifth insulating layer 50. Accordingly, the first etching depth DH2a may be shorter than the second etching depth DH2b.

As described above, the metal layer ML serving as an etch stopper may allow for a portion of the fifth insulating layer 50 to be etched, and may prevent the fourth insulating layer 40 from being etched. Accordingly, the excessive dehydrogenation is prevented, such that the display panel DP (see FIG. 8A) exhibiting increased reliability is manufactured.

Referring to FIG. 11C, the organic layer ORP may be disposed in the opening BA-OP, and the groove BA-GV and the first organic insulating layer 60 may be formed. Although not illustrated, the second organic insulating layer 70 (see FIG. 8A) may be formed on the first organic insulating layer 60, such that the display panel DP may be formed as illustrated in FIG. 8A.

FIGS. 12A to 12C are views schematically illustrating steps of manufacturing a display panel according to one or more embodiments of the present disclosure. In the following description made with reference to FIGS. 12A to 12C, repeated descriptions made with reference to FIGS. 1 to 11C will be omitted to avoid redundancy. The following descriptions will be made while focusing on the differences.

The method for manufacturing the display panel illustrated in FIGS. 12A to 12C may omit forming the metal layer ML (see FIG. 11B), which differs from the method for manufacturing the display panel described with reference to FIGS. 11A to 11C.

Referring to FIGS. 12A and 12B, a photoresist PR may be applied on an entire portion of the top surface of the fifth insulating layer 50, before forming the opening BA-OP and the groove BA-GV. An opening pattern PT1 and a groove pattern PT2 may be formed by etching a portion of the photoresist PR.

The opening pattern PT1 may correspond to the position for forming the opening BA-OP, and the groove pattern PT2 may correspond to the position for forming the groove BA-GV. The opening pattern PT1 and the groove pattern PT2 may be formed to have mutually different depths using a mask MSK. The mask MSK may be a half tone mask. For example, the half tone mask MSK may include a transmissive part R1, a semi-transmissive part R3, and a light shielding part R2. The opening pattern PT1 may be formed in a portion corresponding to the transmissive part R1, and the groove pattern PT2 may be formed in a portion corresponding to the semi-transmissive part R3. Although the above description has been made for an example case in which positive photoresist is used, the embodiment is not limited thereto. Negative photoresist to remove a portion which is not exposed may be used.

The depth of the opening pattern PT1 may be greater than the depth of the groove pattern PT2 in the thickness direction DR3. Accordingly, a portion of the top surface of the fifth insulating layer 50 may be exposed according to the opening pattern PT1. The groove pattern PT2 may be of a depth such that the top surface of the fifth insulating layer 50 is not exposed.

Thereafter, the opening BA-OP may be formed by etching the first to fifth insulating layers 10 to 50 according to the opening pattern PT1, and the groove BA-GV may be formed by etching a portion (e.g., an upper portion, without etching lower portions) of the fifth insulating layer 50 according to the groove pattern PT2. The photoresist PR may be removed after forming the opening BA-OP and the groove BA-GV.

Referring to FIG. 12C, the organic layer ORP may be disposed in the opening BA-OP and the groove BA-GV and the first organic insulating layer 60 may be formed. Although not illustrated, the second organic insulating layer 70 (see FIG. 8A) may be formed on the first organic insulating layer 60, such that the display panel DP may be formed as illustrated in FIG. 8A.

According to an embodiment, the method for manufacturing the display panel may include forming the transistor and the insulating layer on the base layer including the boundary region and the pixel region. The transistor may be formed by forming the semiconductor pattern and the gate, and the opening and the groove may be formed in the insulating layer covering the gate. The opening may be formed such that the opening corresponds to the boundary region. The opening may be formed through the insulating layer, which covers the gate, from the top surface of the insulating layer to the bottom surface of the insulating layer. The groove may be spaced apart from the opening, formed through a portion (e.g., an upper portion, without etching lower portions) of the insulating layer, which covers the gate, and spaced apart from the bottom surface of the insulating layer which covers the gate. The metal layer may be disposed or the half tone mask may be provided to form the groove. As the groove is formed through a portion (e.g., an upper portion, without etching lower portions) of the insulating layer, deterioration of characteristics (e.g., reliability) due to excessive dehydrogenation may be prevented. According to an embodiment, in the method for manufacturing the display panel, the display panel may include the groove formed through the portion of the insulating layer to exhibit improved reliability.

According to an embodiment, in the method for manufacturing a display panel, a display panel maintaining impact resistance while exhibiting improved reliability according to an embodiment may be manufactured by including forming the groove through a portion (e.g., an upper portion, without etching lower portions) of the insulating layer.

According to an embodiment, the display panel includes the groove formed through only the portion of the insulating layer to maintain impact resistance while exhibiting improved reliability.

Although an embodiment of the present disclosure has been described for illustrative purposes, those skilled in the art will appreciate that various modifications, and substitutions are possible, without departing from the scope and spirit of the aspects of the present disclosure as disclosed in the accompanying claims.

Accordingly, the technical scope of the inventive concept is not limited to the detailed description of this specification, but should be defined by the claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display panel comprising:
a base layer including a boundary region and a pixel region;
a pixel circuit overlapped with the pixel region and including a first transistor including a first semiconductor pattern and a first gate; and
a plurality of insulating layers, wherein an opening defined in the plurality of insulating layers corresponds to the boundary region,
wherein a first insulating layer of the plurality of insulating layers covers the first gate, and a groove defined in the first insulating layer is spaced apart from the opening, and
wherein the groove is formed through a portion of the first insulating layer.

2. The display panel of claim 1, wherein the groove is overlapped by the first semiconductor pattern.

3. The display panel of claim 1, wherein the opening is formed through the plurality of insulating layers.

4. The display panel of claim 1, wherein a depth of the opening is greater than a depth of the groove, in a thickness direction.

5. The display panel of claim 1, further comprising:
a metal layer disposed at a layer the same as a layer at which the first gate is disposed.

6. The display panel of claim 5, wherein a surface of the metal layer is exposed by the groove.

7. The display panel of claim 5, wherein the metal layer comprises at least one of aluminum (Al), molybdenum (Mo), titanium (Ti), and indium gallium zinc oxide (IGZO).

8. The display panel of claim 1, wherein the pixel circuit further comprises:
a second transistor including a second semiconductor pattern and a second gate, wherein the second transistor is disposed at a layer different from a layer at which the first transistor is disposed.

9. The display panel of claim 8, wherein:
the first semiconductor pattern includes an oxide semiconductor, and
the second semiconductor pattern includes a silicon semiconductor.

10. A display panel comprising:
a base layer including a boundary region and a pixel region;
a pixel circuit overlapped with the pixel region and including a first transistor including a first semiconductor pattern and a first gate; and
a plurality of insulating layers, wherein an opening defined in the plurality of insulating layers corresponds to the boundary region,
wherein a distance between the first semiconductor pattern and the opening is 5 μm or more and 70 μm or less in a direction perpendicular to a thickness direction.

11. The display panel of claim 10, wherein the opening is formed through the plurality of insulating layers.

12. The display panel of claim 10, wherein the first semiconductor pattern includes an oxide semiconductor.

13. The display panel of claim 10, further comprising:
a barrier layer disposed on the base layer,
wherein the barrier layer is exposed by the opening.

14. The display panel of claim 10, wherein the pixel circuit comprises:
a second transistor including a second semiconductor pattern and a second gate, wherein the second transistor is disposed at a layer different from a layer at which the first transistor is disposed, and
wherein the second semiconductor pattern includes a silicon semiconductor.

15. A method for manufacturing a display panel, the method comprising:
preparing a base layer including a boundary region and a pixel region;
forming a transistor overlapped with the pixel region and including a semiconductor pattern and a gate; and
forming an insulating layer covering the gate,
wherein an opening corresponding to the boundary region and a groove spaced apart from the opening are formed in the forming of the insulating layer, and
wherein the groove is formed through a portion of the insulating layer.

16. The method of claim 15, further comprising:
forming a metal layer overlapped with the semiconductor pattern, after forming the transistor and before forming the insulating layer.

17. The method of claim 16, wherein the metal layer comprises at least one of aluminum (Al), molybdenum (Mo), titanium (Ti), and indium gallium zinc oxide (IGZO).

18. The method of claim 15, further comprising:
etching the insulating layer, wherein the groove and the opening are formed by etching the insulating layer, and
wherein a first etching depth associated with forming the groove is less than a second etching depth associated with forming the opening.

19. The method of claim 15, wherein the forming of the groove and the opening is based on a half tone mask.

20. The method of claim 15, wherein the semiconductor pattern comprises an oxide semiconductor.
